(19) United States
(12) Patent Application Publication
(10) Pub. No.: US 2024/0305066 A1
(43) Pub. Date: Sep. 12, 2024

(54) LIGHT-EMITTING DEVICE

(71) Applicant: NICHIA CORPORATION, Anan-shi, Tokushima (JP)

(72) Inventor: Hiroshi MARUYAMA, Anan-shi (JP)

(21) Appl. No.: 18/594,502

(22) Filed: Mar. 4, 2024

(30) Foreign Application Priority Data
Mar. 6, 2023 (JP) 2023-033528

(51) Int. Cl. H01S 5/40; H01S 5/02253; H01S 5/02255; H01S 5/02375

(52) U.S. Cl. CPC H01S 5/4093; H01S 5/02253; H01S 5/02255; H01S 5/02375

(57) ABSTRACT

A light-emitting device includes a base, first to third light-emitting elements, one or more reflective members, and a lens member. The second and third light-emitting elements are disposed on lateral sides of the first light-emitting element, respectively. The mounting surface of the base is warped such that positions where the second and third light-emitting elements are disposed are lower than a position where the first light-emitting element is disposed, and the light-emitting surfaces of the second and third light-emitting elements are located more on a front side than the light-emitting surface of the first light-emitting element, or the positions where the second and third light-emitting elements are disposed are higher than the position where the first light-emitting element is disposed, and the light-emitting surfaces of the second and third light-emitting elements are both located more on a back side than the light-emitting surface of the first light-emitting element.

### CROSS-REFERENCE TO RELATED APPLICATION

This application claims priority to Japanese Patent Application No. 2023-033528, filed on Mar. 6, 2023, the disclosure of which is hereby incorporated herein by reference in its entirety.

### TECHNICAL FIELD

The present disclosure relates to a light-emitting device.

### BACKGROUND

Japanese Patent Publication Nos. 2021-97216 and 2023-023799 disclose a light-emitting device in which a plurality of light-emitting elements are arranged side by side and light emitted from each of the plurality of light-emitting elements is reflected upward by a reflective member and is caused to be incident on an optical member having a lens surface.

### SUMMARY

There is room for improving the quality of light emitted from the light-emitting device.

A light-emitting device disclosed in an embodiment includes a base, a first light-emitting element, a second light-emitting element, a third light-emitting element, one or more reflective members, and a lens member. The base has a mounting surface. The first light-emitting element is disposed over the mounting surface and configured to emit light forward from a light-emitting surface. The second light-emitting element is disposed over the mounting surface at a position on a first lateral side of the first light-emitting element and spaced apart from the first light-emitting element in a first direction. The second light-emitting element is configured to emit light forward from a light-emitting surface. The third light-emitting element is disposed over the mounting surface at a position on a second lateral side of the first light-emitting element and spaced apart from the first light-emitting element in a second direction opposite to the first direction. The third light-emitting element is configured to emit light forward from a light-emitting surface. One or more reflective members are disposed at a position spaced apart from the first light-emitting element, the second light-emitting element, and the third light-emitting element in a forward direction. The one or more reflective members are configured to reflect the light emitted from a corresponding one of the first light-emitting element, the second light-emitting element, and the third light-emitting element upward. The lens member is disposed above the one or more reflective members and including a first lens portion through which the light emitted from the first light-emitting element passes, a second lens portion through which the light emitted from the second light-emitting element passes, and a third lens portion through which the light emitted from the third light-emitting element passes. The mounting surface of the base is warped such that a position on the mounting surface where the second light-emitting element is disposed and a position on the mounting surface where the third light-emitting element is disposed are lower than a position on the mounting surface where the first light-emitting element is disposed, and the light-emitting surface of the second light-emitting element and the light-emitting surface of the third light-emitting element are both located more on a front side than the light-emitting surface of the first light-emitting element. The mounting surface of the base is warped such that the position where the second light-emitting element is disposed and the position where the third light-emitting element is disposed are higher than the position where the first light-emitting element is disposed, and the light-emitting surface of the second light-emitting element and the light-emitting surface of the third light-emitting element are both located more on a back side than the light-emitting surface of the first light-emitting element.

A light-emitting device disclosed in an embodiment includes a base, a first light-emitting element, a second light-emitting element, a third light-emitting element, one or more reflective members, and a lens. The base has a mounting surface. The first light-emitting element is disposed over the mounting surface and configured to emit light forward from a light-emitting surface. The second light-emitting element is disposed over the mounting surface at a position on a first lateral side of the first light-emitting element and spaced apart from the first light-emitting element in a first direction, the second light-emitting element being configured to emit light forward from a light-emitting surface. The third light-emitting element is disposed over the mounting surface at a position on a second lateral side of the first light-emitting element and spaced apart from the first light-emitting element in a second direction opposite to the first direction, the third light-emitting element configured to emit light forward from a light-emitting surface. The one or more reflective members are disposed at a position spaced apart from the first light-emitting element, the second light-emitting element, and the third light-emitting element in a forward direction. The one or more reflective members are configured to reflect the light emitted from a corresponding one of the first light-emitting element, the second light-emitting element, and the third light-emitting element upward. The lens member is disposed above the one or more reflective members and including a first lens portion through which the light emitted from the first light-emitting element passes, a second lens portion through which the light emitted from the second light-emitting element passes, and a third lens portion through which the light emitted from the third light-emitting element passes. The light-emitting surface of the first light-emitting element and the light-emitting surface of the second light-emitting element are offset in a front-rear direction according to a difference between a height of the mounting surface at a position where the first light-emitting element is disposed and a height of the mounting surface at a position where the second light-emitting element is disposed. The light-emitting surface of the first light-emitting element and the light-emitting surface of the third light-emitting element are offset in the front-rear direction according to a difference between the height of the mounting surface at the position where the first light-emitting element is disposed and a height of the mounting surface at a position where the third light-emitting element is disposed.

In at least one of one or a plurality of the embodiments, the light emitted from each of the plurality of light-emitting elements can be emitted from the light-emitting device while reducing a difference between mutual optical path lengths, and the quality of the light emitted from the light-emitting device can be improved.

### BRIEF DESCRIPTION OF DRAWINGS

FIG. 1 is a perspective view of a light-emitting device according to a first embodiment.

FIG. 2 is a top view of the light-emitting device according to the first embodiment.

FIG. 3A is a perspective view for describing each component disposed inside the light-emitting device according to the first embodiment.

FIG. 3B is a top view in a state of FIG. 3A.

FIG. 4 is a cross-sectional view of a base taken along a cross-sectional line IV-IV in FIG. 3B.

FIG. 5A is a schematic diagram for describing an example of a position of each of light-emitting surfaces of a plurality of light-emitting elements in the light-emitting device according to the first embodiment.

FIG. 5B is a schematic diagram for describing another example of a position of each of the light-emitting surfaces of the plurality of light-emitting elements in the light-emitting device according to the first embodiment.

FIG. 6A is a schematic diagram for describing an example of an optical path length of light passing through an optical axis until it reaches a lens surface since being reflected by a light reflective surface in the light-emitting device according to the first embodiment.

FIG. 6B is a schematic diagram for describing another example of an optical path length of the light passing through the optical axis until it reaches the lens surface since being reflected by the light reflective surface in the light-emitting device according to the first embodiment.

FIG. 7 is a perspective view of a light-emitting device according to a second embodiment and a third embodiment.

FIG. 8 is a top view of the light-emitting device according to the second embodiment and the third embodiment.

FIG. 9 is a top view for describing each component disposed inside the light-emitting device according to the second embodiment and the third embodiment.

FIG. 10A is a schematic diagram for describing an example of a position of each of light-emitting surfaces of a plurality of light-emitting elements in the light-emitting device according to the second embodiment.

FIG. 10B is a schematic diagram for describing another example of a position of each of the light-emitting surfaces of the plurality of light-emitting elements in the light-emitting device according to the second embodiment.

FIG. 11A is a schematic diagram for describing an example of a position of each of light-emitting surfaces of a plurality of light-emitting elements in the light-emitting device according to the third embodiment.

FIG. 11B is a schematic diagram for describing another example of a position of each of the light-emitting surfaces of the plurality of light-emitting elements in the light-emitting device according to the third embodiment.

FIG. 12A is a schematic diagram illustrating another example (first example) of a position of each of light-emitting surfaces of a plurality of light-emitting elements in a light-emitting device according to an embodiment.

FIG. 12B is a schematic diagram illustrating another example (second example) of a position of each of the light-emitting surfaces of the plurality of light-emitting elements in the light-emitting device according to the embodiment.

FIG. 12C is a schematic diagram illustrating another example (third example) of a position of each of the light-emitting surfaces of the plurality of light-emitting elements in the light-emitting device according to the embodiment.

FIG. 12D is a schematic diagram illustrating another example (fourth example) of a position of each of the light-emitting surfaces of the plurality of light-emitting elements in the light-emitting device according to the embodiment.

FIG. 12E is a schematic diagram illustrating another example (fifth example) of a position of each of the light-emitting surfaces of the plurality of light-emitting elements in the light-emitting device according to the embodiment.

FIG. 12F is a schematic diagram illustrating another example (sixth example) of a position of each of the light-emitting surfaces of the plurality of light-emitting elements in the light-emitting device according to the embodiment.

FIG. 12G is a schematic diagram illustrating another example (seventh example) of a position of each of the light-emitting surfaces of the plurality of light-emitting elements in the light-emitting device according to the embodiment.

FIG. 12H is a schematic diagram illustrating another example (eighth example) of a position of each of the light-emitting surfaces of the plurality of light-emitting elements in the light-emitting device according to the embodiment.

FIG. 12I is a schematic diagram illustrating another example (ninth example) of a position of each of the light-emitting surfaces of the plurality of light-emitting elements in the light-emitting device according to the embodiment.

FIG. 12J is a schematic diagram illustrating another example (tenth example) of a position of each of the light-emitting surfaces of the plurality of light-emitting elements in the light-emitting device according to the embodiment.

FIG. 12K is a schematic diagram illustrating another example (eleventh example) of a position of each of the light-emitting surfaces of the plurality of light-emitting elements in the light-emitting device according to the embodiment.

FIG. 12L is a schematic diagram illustrating another example (twelfth example) of a position of each of the light-emitting surfaces of the plurality of light-emitting elements in the light-emitting device according to the embodiment.

FIG. 12M is a schematic diagram illustrating another example (thirteenth example) of a position of each of the light-emitting surfaces of the plurality of light-emitting elements in the light-emitting device according to the embodiment.

FIG. 12N is a schematic diagram illustrating another example (fourteenth example) of a position of each of the light-emitting surfaces of the plurality of light-emitting elements in the light-emitting device according to the embodiment.

FIG. 12O is a schematic diagram illustrating another example (fifteenth example) of a position of each of the light-emitting surfaces of the plurality of light-emitting elements in the light-emitting device according to the embodiment.

FIG. 12P is a schematic diagram illustrating another example (sixteenth example) of a position of each of the light-emitting surfaces of the plurality of light-emitting elements in the light-emitting device according to the embodiment.

FIG. 12Q is a schematic diagram illustrating another example (seventeenth example) of a position of each of the light-emitting surfaces of the plurality of light-emitting elements in the light-emitting device according to the embodiment.

FIG. 12R is a schematic diagram illustrating another example (eighteenth example) of a position of each of the light-emitting surfaces of the plurality of light-emitting elements in the light-emitting device according to the embodiment.

### DETAILED DESCRIPTIONS

In the present description or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present description and the claims.

The same applies not only to polygons but also to words representing specific shapes such as trapezoids, circles, protrusions, and recessions. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present description or the scope of the claims, descriptions such as upper/upward and lower/downward, left and right, surface and reverse, front and back (forward/backward), and near and far are used merely to describe the relative relationship of positions, orientations, directions, and the like, and the expressions need not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with an X, Y, and Z are the positive directions, and the opposite directions are the negative directions. For example, the direction marked with an X at the tip of the arrow is the X direction and the positive direction. The direction, which is the X direction and is the positive direction, will be referred to as the “positive direction of X” and the direction opposite to this will be referred to as the “negative direction of X”. The same applies to the Y direction and Z direction.

The term “member” or “portion” may be used to describe a component or the like in the present description. The term “member” refers to an object physically treated alone. The object physically treated alone can be referred to as an object treated as one part in a manufacturing step. On the other hand, the term “portion” refers to an object that need not be physically treated alone. For example, the term “portion” is used when part of one member is partially considered, a plurality of members are collectively considered as one object, or the like.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present description and the claims, when a plurality of components are present and these components are to be indicated separately, the components may be distinguished by adding the terms “first” and “second” at the beginning of the names of the components. Objects to be distinguished may differ between the present description and the claims. Thus, even when a component in the claims is given the same term as that in the present description, the object identified by that component is not the same across the present description and the claims in some cases.

For example, when components distinguished by being termed “first”, “second”, and “third” are present in the present description and components given the terms “first” and “third” in the present description are described in the claims, these components may be distinguished by being denoted as “first” and “second” in the claims for ease of understanding. In this case, the components denoted as “first” and “second” in the claims refer to the components termed “first” and “third” in the present description, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments. That is, the embodiments illustrated by the drawings are not an only form in which the present invention is achieved. Sizes, positional relationships, and the like of members illustrated in each of the drawings may sometimes be exaggerated in order to facilitate understanding.

### First Embodiment

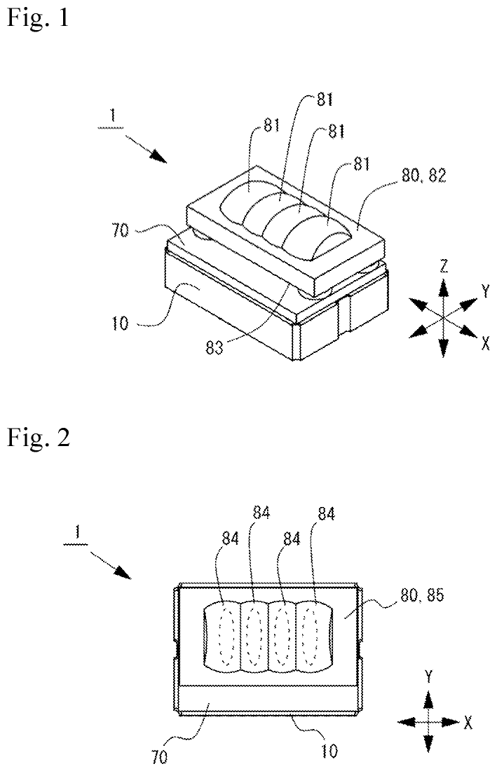

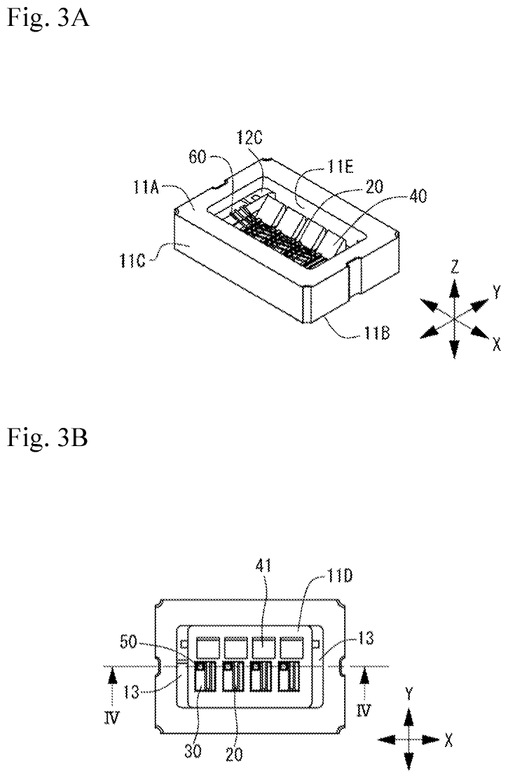

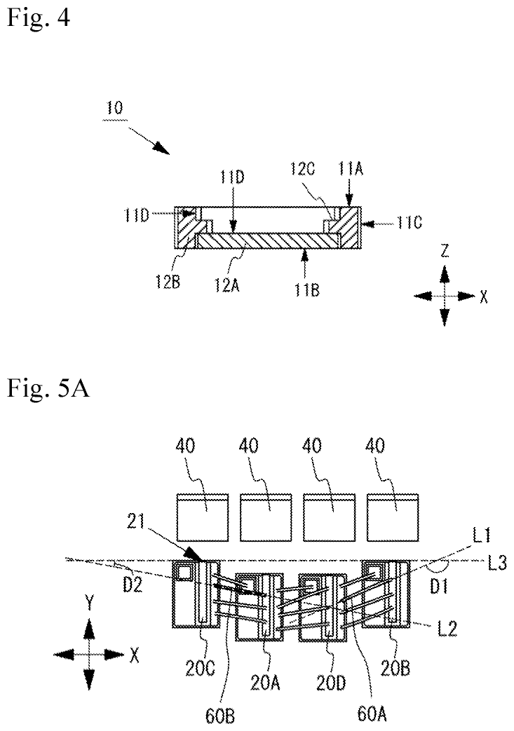

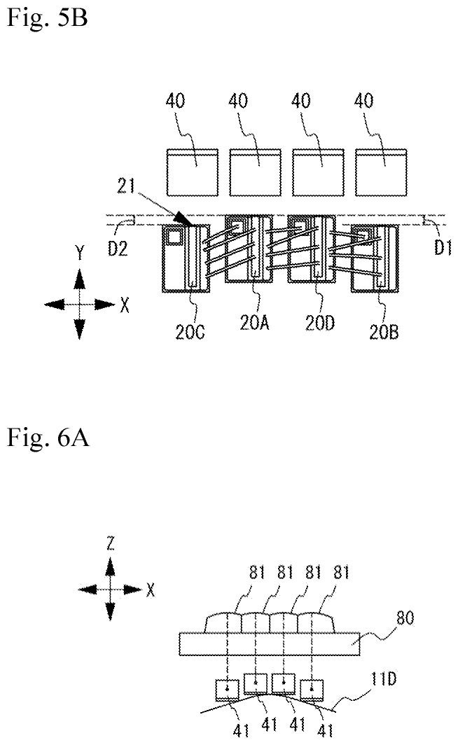

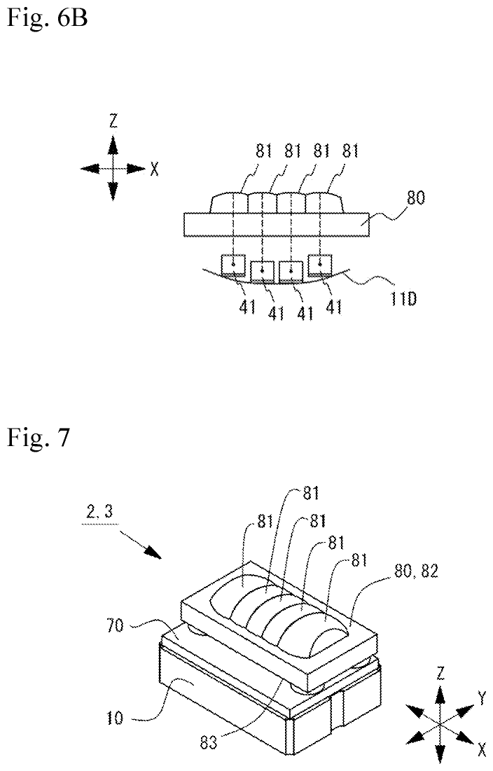

A light-emitting device 1 according to a first embodiment will now be described. FIGS. 1 to 6B are drawings for describing an exemplary form of the light-emitting device 1. FIG. 1 is a schematic perspective view of the light-emitting device 1. FIG. 2 is a schematic top view of the light-emitting device 1. The elliptical dotted lines in FIG. 2 represent outer shapes of lights emitted from the light-emitting device 1. FIG. 3A is a perspective view for describing each component disposed inside the light-emitting device 1. FIG. 3B is a top view in a state of FIG. 3A. FIG. 3B omits wirings 60. FIG. 4 is a cross-sectional view of a base 10 taken along a cross-sectional line IV-IV in FIG. 3B. FIGS. 5A and 5B are diagrams for describing a position of each of light-emitting surfaces 21 of a plurality of light-emitting elements 20 disposed on a mounting surface 11D in the light-emitting device 1. In FIG. 5A, three imaginary straight lines L1, L2, L3 are indicated by dotted lines. FIGS. 6A and 6B are diagrams for describing an optical path length of light emitted from each of the light-emitting elements 20 and passing through an optical axis until it reaches a lens surface 81 of a lens member 80 since being reflected by a light reflective surface 41 of a reflective member 40 in the light-emitting device 1. In FIGS. 6A and 6B, the optical path lengths are indicated by broken lines.

The light-emitting device 1 includes a plurality of components. The plurality of components include the base 10, the plurality of light-emitting elements 20, a plurality of submounts 30, one or a plurality of the reflective members 40, one or a plurality of protective elements 50, a plurality of the wirings 60, a lid member 70, and the lens member 80.

The light-emitting device 1 may include a component other than the components described above. For example, the light-emitting device 1 may further include a light-emitting element different from the plurality of light-emitting elements 20. The light-emitting device 1 need not include some of the components described above. First, each of the components will be described.

### Base 10

The base 10 includes an upper surface 11A, a lower surface 11B, and one or a plurality of outer lateral surfaces 11C. In a top view, an outer edge shape of the base 10 is rectangular. This rectangular shape can be a shape with long sides and short sides. In the base 10 illustrated by the drawings, a long side direction of the rectangle is the same direction as the X direction, and a short side direction thereof is the same direction as the Y direction. The outer edge shape of the base 10 in the top view need not be a rectangular shape.

A recessed shape is formed in the base 10. A recessed shape being recessed downward from the upper surface 11A is formed from the upper surface 11A. The recessed shape defines the recess of the base 10. The recess is surrounded by the upper surface 11A in the top view.

In the top view, an inner edge of the upper surface 11A defines an outer edge of the recess. In the top view, the outer edge shape of the recess is rectangular. This rectangular shape can be a shape with long sides and short sides. In the base 10 illustrated by the drawings, a long side direction of the rectangle is the same direction as the X direction, and a short side direction thereof is the same direction as the Y direction. The outer edge shape of the recess need not be rectangular.

The base 10 includes the mounting surface 11D. The mounting surface 11D is located below the upper surface 11A and above the lower surface 11B. The base 10 includes one or a plurality of inner lateral surfaces 11E. One or the plurality of inner lateral surfaces 11E extend upward from the mounting surface 11D. The one or the plurality of inner lateral surfaces 11E meet the upper surface 11A. The mounting surface 11D and one or the plurality of inner lateral surfaces 11E are a part of or all of a plurality of surfaces defining the recess of the base 10.

The one or the plurality of inner lateral surfaces 11E are provided perpendicular to the mounting surface 11D. The description of “perpendicular” here allows a difference within ±3 degrees. The inner lateral surface 11E need not be perpendicular to the mounting surface 11D.

The base 10 includes a base portion 12A and a frame portion 12B. The upper surface 11A and one or the plurality of outer lateral surfaces 11C are included in the frame portion 12B. The mounting surface 11D is included in the base portion 12A. One or the plurality of inner lateral surfaces 11E are included in the frame portion 12B. The lower surface 11B of the base 10 may be constituted by the lower surface of the base portion 12A and the lower surface of the frame portion 12B. The base 10 may be constituted by only the base portion 12A without substantially including the frame portion 12B.

The frame portion 12B surrounds the mounting surface 11D. In the top view, the mounting surface 11D is surrounded by the frame portion 12B. The frame portion 12B is bonded to the vicinity of the outer edge of the upper surface of the base portion 12A. It can be said that the mounting surface 11D of the base 10 is a region of the upper surface of the base portion 12A that does not overlap with the frame portion 12B in the top view. In addition, it can be said that the outer edge shape of this region is a shape of the frame formed of the frame portion 12B. In the illustrated base 10, the shape of the frame formed of the frame portion 12B is a shape having a width in the X direction wider than a width in the Y direction.

The base 10 includes one or a plurality of stepped portions 12C. The stepped portion 12C includes an upper surface and an inner lateral surface that meets the upper surface and extends downward from the upper surface. The upper surface of the stepped portion 12C meets the inner lateral surface 11E. The inner lateral surface of the stepped portion 12C intersects the mounting surface 11D.

The one or the plurality of stepped portions 12C are included in the frame portion 12B. The stepped portion 12C is formed along a part or the whole of the inner lateral surface 11E in the top view. The one or the plurality of stepped portions 12C are formed inward of the upper surface 11A in the top view. The one or the plurality of stepped portions 12C are formed inward of the one or the plurality of inner lateral surfaces 11E in the top view. The base 10 can include the plurality of stepped portions 12C.

One or a plurality of wiring patterns 13 are provided on the upper surface of the stepped portion 12C. The wiring pattern 13 is electrically connected to another wiring pattern provided on the frame portion 12B via a wiring passing through the inside of the frame portion 12B. The wiring pattern 13 is electrically connected to a wiring pattern provided on the lower surface of the frame portion 12B. The wiring pattern 13 can be electrically connected to a wiring pattern provided on the upper surface 11A or the outer lateral surface 11C of the frame portion 12B. The plurality of wiring patterns 13 can be provided on the upper surface of the one or the plurality of stepped portions 12C.

On each of the plurality of stepped portions 12C, the one or the plurality of wiring patterns 13 can be provided. The base 10 can include the stepped portion 12C including the upper surface on which the plurality of wiring patterns 13 are provided.

The base portion 12A and the frame portion 12B of the base 10 can be formed of members containing different materials as their main materials. The base 10 can be formed by bonding a member constituting the base portion 12A and a member constituting the frame portion 12B. In the illustrated base 10, the base portion 12A is formed of a flat plate-like member, and the frame portion 12B is formed of a frame-shaped member.

Here, the main material refers to a material that occupies the greatest proportion of a target formed product in terms of weight or volume. When a target formed product is formed of one material, that material is the main material. In other words, when a certain material is the main material, the proportion of that material may be 100%.

In the base 10, a ceramic can be employed as the main material of the frame-shaped member by which the frame portion 12B is formed, and a metal can be employed as the main material of the flat plate-like member by which the base portion 12A is formed. The metal as the main material of the flat plate-like member is not limited to a single metal, and can be an alloy containing a plurality of metals or a composite containing a metal. The base 10 in which the base portion 12A and the frame portion 12B are integrally formed can be employed. In this case, for example, the base 10 can be formed using a ceramic as the main material.

Examples of the ceramic include aluminum nitride, silicon nitride, aluminum oxide, and silicon carbide. Examples of the metal include copper, aluminum, and iron. As the composite containing a metal, copper molybdenum, a copper-diamond composite material, copper tungsten, or the like can be used.

By forming the base portion 12A separately from the frame portion 12B, properties different from those of the frame portion 12B can be provided to the base portion 12A. For example, when the metal employed for the base portion 12A has a better heat dissipation property (higher thermal conductivity) than the ceramic employed for the frame portion 12B does, heat generated from the components mounted on the mounting surface 11D can be easily released. In addition, by providing the wiring pattern 13 on the stepped portion 12C of the frame portion 12B, while the base portion 12A is formed of a conductive material, such as a metallic plate, a region for wiring connection can be ensured.

The mounting surface 11D of the base 10 is warped. Although the mounting surface 11D of the base 10 is ideally a flat surface, strictly speaking, the mounting surface 11D is warped. Such a warp is caused when the base 10 is manufactured or when the light-emitting device 1 is manufactured. For example, a warp is possibly caused due to processing accuracy, a temperature difference in the manufacturing process, or the like. For example, when the base 10 is formed by bonding the base portion 12A formed of a metal and the frame portion 12B formed of a ceramic, a warp is caused due to a difference in coefficient of thermal expansion between the base portion 12A and the frame portion 12B.

The shape of the warp of the mounting surface 11D of the base 10 is a shape such that the height of the mounting surface 11D at a position away from the center of the warp is lower than the height of the center of the warp. The center of the warp of the mounting surface 11D here indicates the highest position in the mounting surface 11D, and does not necessarily match the center on the coordinates of the mounting surface 11D. However, the center of the warp is considered typically at a position close to the center on the coordinates.

In addition, the mounting surface 11D of the base 10 can have a shape of the warp such that the height of the mounting surface 11D at the position away from the center of the warp is higher than the height of the center of the warp. In this case, the center of the warp of the mounting surface 11D indicates the lowest position in the mounting surface 11D. Also in this case, the center of the warp need not match the center on the coordinates, but the center of the warp is considered to be typically located at a position close to the center on the coordinates. The direction of the warp of the mounting surface 11D possibly changes depending on a difference in the material, the shape, the manufacturing process, and the like.

### Light-Emitting Element 20

The light-emitting element 20 includes a light-emitting surface that emits light. The light-emitting element 20 includes an upper surface, a lower surface, and a plurality of lateral surfaces. One of the lateral surfaces of the light-emitting element 20 serves as the light-emitting surface 21. The light-emitting element 20 includes one or a plurality of light-emitting surfaces.

A shape of the upper surface of the light-emitting element 20 is a rectangular shape having long sides and short sides. The shape of the upper surface of the light-emitting element 20 need not be a rectangle. A semiconductor laser element can be employed for the light-emitting element 20. The light-emitting element 20 is not limited to a semiconductor laser element, and a light-emitting diode or the like can be employed.

As the light-emitting element 20, for example, a light-emitting element that emits blue light, a light-emitting element that emits green light, or a light-emitting element that emits red light can be employed. A light-emitting element that emits light of another color may be employed as the light-emitting element 20.

Blue light refers to light having an emission peak wavelength within a range from 420 nm to 494 nm. Green light refers to light having an emission peak wavelength within a range from 495 nm to 570 nm. Red light refers to light having an emission peak wavelength within a range from 605 nm to 750 nm.

Here, a semiconductor laser element being an example of the light-emitting element 20 will be described. The semiconductor laser element has a rectangular external shape having one set of opposite sides as long sides and another set of opposite sides as short sides in a top view. Light (laser beam) emitted from the semiconductor laser element spreads. Further, divergent light is emitted from an emission end surface of the semiconductor laser element. The emission end surface of the semiconductor laser element can be referred to as the light-emitting surface 21 of the light-emitting element 20.

The light emitted from the semiconductor laser element forms a far field pattern (hereinafter referred to as an “FFP”) of an elliptical shape in a plane parallel to the emission end surface of the light. The FFP indicates a shape and a light intensity distribution of the emitted light at a position spaced apart from the emission end surface.

Here, light passing through the center of the elliptical shape of the FFP, in other words, light having a peak intensity in the light intensity distribution of the FFP is referred to as light traveling along an optical axis or light passing through an optical axis. Based on the light intensity distribution of the FFP, light having an intensity of 1/e² or more with respect to a peak intensity value is referred to as a main portion of the light.

The shape of the FFP of the light emitted from the semiconductor laser element is an elliptical shape in which the light is longer in a layering direction than in a direction perpendicular to the layering direction in the plane parallel to the emission end surface of the light. The layering direction is a direction in which a plurality of semiconductor layers including an active layer are layered in the semiconductor laser element. The direction perpendicular to the layering direction can also be referred to as a plane direction of the semiconductor layers. Further, a long diameter direction of the elliptical shape of the FFP can also be referred to as a fast axis direction of the semiconductor laser element, and a short diameter direction can also be referred to as a slow axis direction of the semiconductor laser element.

Based on the light intensity distribution of the FFP, an angle at which light having a light intensity of 1/e² of a peak light intensity spreads is referred to as a divergence angle of light of the semiconductor laser element. For example, a divergence angle of light may also be determined based on the light intensity that is half of the peak light intensity, other than being determined based on the light intensity of 1/e² of the peak light intensity. In the present description herein, the term “divergence angle of light” by itself refers to a divergence angle of light at the light intensity of 1/e² of the peak light intensity. It can be said that a divergence angle in the fast axis direction is greater than a divergence angle in the slow axis direction.

Examples of a semiconductor laser element that emits blue light or a semiconductor laser element that emits green light include a semiconductor laser element including a nitride semiconductor. GaN, InGaN, or AlGaN, for example, can be used as the nitride semiconductor. Examples of the semiconductor laser element that emits red light include a semiconductor laser element including an InAlGaP-based, GaInP-based, GaAs-based, or AlGaAs-based semiconductor.

### Submount 30

The submount 30 includes two bonding surfaces and is formed in a rectangular parallelepiped shape. The upper surface of the submount 30 has a rectangular shape. The upper surface of the submount 30 can have a rectangular shape with short sides and long sides.

On an opposite side from one bonding surface of the submount 30, the other bonding surface is provided. A distance between the two bonding surfaces is smaller than a distance between other opposed two surfaces. The shape of the submount 30 is not limited to the rectangular parallelepiped shape. The submount 30 can be formed using, for example, silicon nitride, aluminum nitride, or silicon carbide. Further, a metal film for bonding is provided on the bonding surfaces.

### Reflective Member 40

The reflective member 40 includes the light reflective surface 41 that reflects light. The light reflective surface 41 is inclined relative to the lower surface. In other words, the light reflective surface 41 is neither perpendicular nor parallel in an arrangement relationship when viewed from the lower surface. A straight line connecting a lower end and an upper end of the light reflective surface 41 is inclined relative to the lower surface of the reflective member 40. An angle of the light reflective surface 41 with respect to the lower surface, or an angle of the straight line connecting the lower end and the upper end of the light reflective surface 41 with respect to the lower surface is referred to as an inclination angle of the light reflective surface.

In the reflective member 40 illustrated by the drawings, the light reflective surface 41 is a flat surface and forms an inclination angle of 45 degrees with respect to the lower surface of the reflective member 40. The light reflective surface 41 need not be a flat surface, and can be, for example, a curved surface. The light reflective surface 41 need not have an inclination angle of 45 degrees.

For the reflective member 40, glass, metal, or the like can be used as a main material. As the main material, a heat-resistant material is preferable, and for example, glass such as quartz glass or borosilicate glass (BK7), or a metal such as aluminum can be employed. The reflective member 40 can also be formed using Si as the main material. When the main material is a reflective material, the light reflective surface 41 can be formed of the main material. When the light reflective surface 41 is formed of a material different from the main material, the light reflective surface 41 can be formed using, for example, a metal, such as Ag or Al, or a dielectric multilayer film of Ta₂O₅/SiO₂, TiO₂/SiO₂, Nb₂O₅/SiO₂, or the like.

The light reflective surface 41 is formed such that a reflectance to the peak wavelength of the light emitted to the light reflective surface 41 is 90% or more. The reflectance can be equal to or more than 95%. The reflectance can be equal to or more than 99%. The light reflectance is equal to or less than 100%or is less than 100%.

### Protective Element 50

The protective element 50 prevents breakage of a specific element (the light-emitting element 20, for example) as a result of an excessive current flowing through the element. The protective element 50 is a Zener diode, for example. A Zener diode formed of Si can be used as the Zener diode.

### Wiring 60

The wiring 60 is a linear conductive material with bonding portions at both ends. The bonding portions at both ends are joint portions with other components. The wiring 60 is, for example, a metal wire. For example, gold, aluminum, silver, copper, or the like can be used as the metal.

### Lid Member 70

The lid member 70 includes a lower surface and an upper surface, and is formed in a flat plate-like rectangular parallelepiped shape. The shape thereof need not be the rectangular parallelepiped shape. For example, the lid member 70 can include a flat plate-like portion and a frame-shaped portion extending downward from the flat plate-like portion.

The lid member 70 has transmissivity to transmit light. The lid member 70 has a light transmittance of 80% or more. The lid member 70 need not have the transmittance of 80% or more for light at all wavelengths. The lid member 70 can partially include a non-light transmissive region. The non-light transmissive region can be a region where the light transmittance is 50% or less, for example.

The lid member 70 is formed using glass as a main material. The main material of the lid member 70 is a material having high transmissivity. The lid member 70 is not limited to glass, and can be formed using sapphire as the main material, for example.

### Lens Member 80

The lens member 80 includes one or a plurality of the lens surfaces 81. The lens member 80 has an upper surface 82, a lower surface 83, and lateral surfaces. The lens member 80 gives an optical action, such as condensing, diffusion, or collimation, to light that passes through the lens surface 81 and exits from the lens member 80. For example, the lens member 80 is a collimating lens that collimates light incident on the lens member 80 and from which the light exits as collimated light.

One or the plurality of lens surfaces 81 are provided on the upper surface 82 side of the lens member 80. One or the plurality of lens surfaces 81 can be provided on the lower surface 83 side of the lens member 80. The upper surface 82 and the lower surface 83 are flat surfaces. The one or the plurality of lens surfaces 81 meet the upper surface 82. The one or the plurality of lens surfaces 81 are surrounded by the upper surface 82 in the top view. In the top view, the lens member 80 has a rectangular outer shape. The lower surface 83 of the lens member 80 is rectangular.

In the lens member 80, a portion overlapping with one or the plurality of lens surfaces 81 in the top view is a lens portion 84. In the lens member 80, a portion overlapping with the upper surface 82 in the top view is a non-lens portion 85. When the lens portion 84 is divided into two in an imaginary plane including and parallel to the upper surface 82, a lens surface side is a lens-shape portion, and a lower surface side is a flat plate-like portion. It can be said that the lower surface of the lens portion 84 is a part of a region of the lower surface 83 of the lens member 80. It can be said that the lower surface 83 of the lens member 80 is formed of the lower surface of the lens portion 84 and a lower surface of the non-lens portion 85.

The lens member 80 can include the plurality of lens surfaces 81. Accordingly, the lens member 80 can include a plurality of the lens portions 84. Further, the plurality of lens surfaces 81 can be continuously formed in one direction. Accordingly, the plurality of lens portions 84 can be linked together. In the top view, a direction in which the plurality of lens surfaces 81 are arranged is referred to as a linked direction. In the lens member 80 illustrated by the drawings, the linked direction is the same direction as the X direction.

The plurality of lens portions 84 are formed such that apexes of the lens surfaces 81 of the lens portions 84 are provided on a straight line. An imaginary straight line connecting the apexes is parallel to the lower surface 83 of the lens member 80. The term “parallel” here includes a difference within ±2 degrees.

A part or all of the plurality of lens surfaces 81 which are two or more of the lens surfaces 81 can have the same curvature. The plurality of lens surfaces 81 can all have the same curvature.

The lens member 80 has transmissivity. The lens member 80 has a light transmittance of 80% or more. The lens member 80 need not have a transmittance of 80% or more for light at all wavelengths. The lens member 80 can partially include a non-light transmissive region. The non-light transmissive region can be a region where the light transmittance is 50% or less, for example. The lens member 80 can be formed using glass such as BK7, for example.

### Light-Emitting Device 1

Subsequently, the light-emitting device 1 including the above-described components will be described.

In the light-emitting device 1, the plurality of light-emitting elements 20 are disposed over the mounting surface 11D. The plurality of light-emitting elements 20 can be all semiconductor laser elements. The frame portion 12B of the base 10 surrounds the plurality of light-emitting elements 20 in a top view. The plurality of light-emitting elements 20 are each disposed with the light-emitting surfaces 21 facing one inner lateral surface 11E of the base 10.

Because the light-emitting elements 20 are disposed over the mounting surface 11D of the base portion 12A containing a metal as the main material, heat generated from the light-emitting elements 20 can be released to the outside through the base portion 12A.

All the light-emitting surfaces 21 of the plurality of light-emitting elements 20 face the same direction. Here, the same direction means that the light-emitting surfaces 21 of all the light-emitting elements 20 face one imaginary plane passing through the mounting surface 11D and perpendicular to the mounting surface 11D. That is, the light-emitting surfaces 21 need not be strictly parallel to one another. The imaginary plane does not extend outward of the mounting surface 11D when viewed from a direction perpendicular to the mounting surface 11D.

In the illustrated light-emitting device 1, lights of FFP having the direction perpendicular to the mounting surface 11D as a fast axis direction are emitted from the light-emitting surfaces 21 of the respective light-emitting elements 20 being semiconductor laser elements. The optical axis of the light emitted from each of the light-emitting elements 20 is parallel to the mounting surface 11D.

Each of the light-emitting elements 20 emits light from the light-emitting surface 21. Here, a direction in which the light is emitted from the light-emitting surface 21 is referred to as a forward direction, and a direction opposite to the forward direction in the top view is referred to as a backward direction. Furthermore, in the top view, a direction perpendicular to the front-rear direction is referred to as a lateral direction. There are two directions opposite to each other in the lateral direction. Of the two directions, one lateral direction is referred to as a first direction, and the other lateral direction is referred to as a second direction. In the illustrated light-emitting device 1, the forward direction is a positive direction of Y, the backward direction is a negative direction of Y, the first direction is a positive direction of X, and the second direction is a negative direction of X.

The plurality of light-emitting elements 20 are arranged side by side on the lateral direction. In addition, the plurality of light-emitting elements 20 can be disposed such that intervals between adjacent ones of the light-emitting elements 20 are equal in the lateral direction. Because the width in the lateral direction is wider than the width in the front-rear direction in the shape of the frame formed of the frame portion 12B, a larger number of the light-emitting elements 20 can be disposed in the lateral direction than in the front-rear direction.

The plurality of light-emitting elements 20 include a first light-emitting element 20A, a second light-emitting element 20B disposed at a position on a first lateral side of the first light-emitting element 20A and spaced apart from the first light-emitting element 20A in the first direction, and a third light-emitting element 20C disposed at a position on a second lateral side of the first light-emitting element 20A and spaced apart from the first light-emitting element 20A in the second direction. The plurality of light-emitting elements 20 further include one or more fourth light-emitting elements 20D disposed between the first light-emitting element 20A and the second light-emitting element 20B.

The second light-emitting element 20B and the third light-emitting element 20C are disposed, on the mounting surface 11D, farther away from the center of the warp than the first light-emitting element 20A. Among the plurality of light-emitting elements 20, the first light-emitting element 20A is the light-emitting element 20 disposed at a position closest to the center of the warp. When there are the plurality of light-emitting elements 20 disposed at the positions closest to the center of the warp, the first light-emitting element 20A is one of those light-emitting elements 20. In the illustrated light-emitting device 1, the first light-emitting element 20A or both the first light-emitting element 20A and the fourth light-emitting element 20D are the light-emitting elements 20 disposed at the positions closest to the center of the warp.

None of the second light-emitting element 20B or the third light-emitting element 20C is the light-emitting element 20 disposed at the position closest to the center of the warp among the plurality of light-emitting elements 20. The second light-emitting element 20B and the third light-emitting element 20C are the light-emitting elements 20 located at both ends among the plurality of light-emitting elements 20 arranged side by side in the lateral direction.

It can be said that the second light-emitting element 20B is the light-emitting element 20 disposed at a position farthest from the first light-emitting element 20A in the first direction among the plurality of light-emitting elements 20 disposed over the mounting surface 11D at positions spaced apart from the first light-emitting element 20A in the first direction. In other words, no light-emitting element is disposed over the mounting surface 11D of the base 10 at a position farther away from or beyond the second light-emitting element 20B in the first direction.

In the light-emitting device 1, both the light-emitting surface 21 of the second light-emitting element 20B and the light-emitting surface 21 of the third light-emitting element 20C are located more on the front side than the light-emitting surface 21 of the first light-emitting element 20A is, or both the light-emitting surface 21 of the second light-emitting element 20B and the light-emitting surface 21 of the third light-emitting element 20C are located more on the back side than the light-emitting surface 21 of the first light-emitting element 20A is. In this way, the lights emitted from the plurality of light-emitting elements 20 can be emitted from the light-emitting device 1 while a difference between the mutual optical path lengths is reduced.

The light-emitting surface 21 of the first light-emitting element 20A and the light-emitting surface 21 of the second light-emitting element 20B are offset in the front-rear direction according to a difference between the height of the mounting surface 11D at the position where the first light-emitting element 20A is disposed and the height of the mounting surface 11D at the position where the second light-emitting element 20B is disposed. In addition, the light-emitting surface 21 of the first light-emitting element 20A and the light-emitting surface 21 of the third light-emitting element 20C are offset in the front-rear direction according to a difference between the height of the mounting surface 11D at the position where the first light-emitting element 20A is disposed and the height of the mounting surface 11D at the position where the third light-emitting element 20C is disposed. In this way, the lights emitted from the plurality of light-emitting elements 20 can be emitted from the light-emitting device 1 while a difference between the mutual optical path lengths is reduced.

At this time, the first light-emitting element 20A, the second light-emitting element 20B, and the third light-emitting element 20C are disposed such that the respective light-emitting surfaces 21 are located according to corresponding distances from the center of the warp of the mounting surface 11D. The extent that the light-emitting surface 21 of the second light-emitting element 20B or the light-emitting surface 21 of the third light-emitting element 20C is offset in the front-rear direction from the light-emitting surface 21 of the first light-emitting element 20A is preferably determined in consideration of the size and the shape of the base 10, the position of each of the light-emitting elements 20 disposed the mounting surface 11D, the positional relationship between the light-emitting elements 20, and the like.

When a large number of the light-emitting devices 1 are manufactured, there is a method in which the heights of the mounting surfaces 11D at the positions of the plurality of light-emitting elements 20 disposed over the mounting surfaces 11D of the individual light-emitting devices 1 is measured and the amounts of offset of the light-emitting surfaces 21 in the front-rear direction is determined. Alternatively, in the case of manufacturing a large number of the light-emitting devices 1, there is a method of determining the amounts of offset based on a statistical amount of offset of the base 10 and disposing the light-emitting elements 20. The former is superior in accuracy as a whole, and the latter is superior in manufacturing efficiency because it does not take time for manufacturing. In either method, the light-emitting surfaces 21 can be disposed in accordance with a difference in the height of the mounting surface 11D at the arrangement positions of the respective light-emitting elements 20, and the realization method is not limited to these two methods.

The light-emitting surface 21 of the second light-emitting element 20B is located more on a front side or a back side than the light-emitting surface 21 of the first light-emitting element 20A is by a range from 1 μm to 50 μm. The light-emitting surface 21 of the third light-emitting element 20C is located more on a front side or a back side than the light-emitting surface 21 of the first light-emitting element 20A is by a range from 1 μm to 50 μm. When the positions are offset in the front-rear direction, the size of the light-emitting device 1 in the front-rear direction may be affected. However, as long as the amount of offset is within this range, the size of the light-emitting device 1 is not significantly increased.

When the warp of the mounting surface 11D has a shape such that the height of the position away from the center of the warp is lower than the height of the center of the warp, the position where the second light-emitting element 20B is disposed and the position where the third light-emitting element 20C is disposed are lower than the position where the first light-emitting element 20A is disposed. At this time, both the light-emitting surface 21 of the second light-emitting element 20B and the light-emitting surface 21 of the third light-emitting element 20C are located more on the front side than the light-emitting surface 21 of the first light-emitting element 20A is (see FIG. 5A).

When the warp of the mounting surface 11D has a shape such that the height of the position away from the center of the warp is higher than the height of the center of the warp, the position where the second light-emitting element 20B is disposed and the position where the third light-emitting element 20C is disposed are higher than the position where the first light-emitting element 20A is disposed. At this time, both the light-emitting surface 21 of the second light-emitting element 20B and the light-emitting surface 21 of the third light-emitting element 20C are located more on the back side than the light-emitting surface 21 of the first light-emitting element 20A is (see FIG. 5B). In this way, the lights emitted from the respective plurality of light-emitting elements 20 can be emitted from the light-emitting device 1 while a difference between the mutual optical path lengths is reduced.

All of the first light-emitting element 20A, the second light-emitting element 20B, and the third light-emitting element 20C emit lights of the same color. The plurality of light-emitting elements 20 are constituted by light-emitting elements that emit lights of the same color. The plurality of light-emitting elements 20 can be constituted by light-emitting elements that emit lights of two or more different colors.

For example, the second light-emitting element 20B emits light of a color different from that of the light emitted from the first light-emitting element 20A, and the third light-emitting element 20C emits light of the same color as that of the light emitted from the first light-emitting element 20A. In addition, for example, the second light-emitting element 20B and the third light-emitting element 20C emit lights of colors different from that of the light emitted from the first light-emitting element 20A. At this time, the third light-emitting element 20C emits light of the same color as that of the light emitted from the second light-emitting element 20B. Alternatively, the third light-emitting element 20C emits light of a color different from that of the light emitted from the second light-emitting element 20B.

The plurality of light-emitting elements 20 that emit light of the same color can be configured such that, in two of the light-emitting elements 20 arbitrarily selected therefrom, a difference between emission peak wavelengths of the lights emitted from the respective light-emitting elements 20 is in a range from 0 nm to 25 nm.

The difference between the respective emission peak wavelengths of the lights emitted from the first light-emitting element 20A and the second light-emitting element 20B can be in a range from 0 nm to 25 nm. The difference between the respective emission peak wavelengths of the lights emitted from the first light-emitting element 20A and the third light-emitting element 20C can be in a range from 0 nm to 25 nm. The difference between the respective emission peak wavelengths of the lights emitted from the second light-emitting element 20B and the third light-emitting element 20C can be in a range from 0 nm to 25 nm.

Here, a distance from the light-emitting surface 21 of the first light-emitting element 20A to the light-emitting surface 21 of the second light-emitting element 20B in the front-rear direction is referred to as a first distance, and a distance from the light-emitting surface 21 of the first light-emitting element 20A to the light-emitting surface 21 of the third light-emitting element 20C in the front-rear direction is referred to as a second distance. As an example, the first distance is denoted as D1 and the second distance is denoted as D2 in FIG. 5B.

In the light-emitting device 1, the light-emitting surface 21 of the second light-emitting element 20B can be located more on the front side or the back side than the light-emitting surface 21 of the first light-emitting element 20A is by the first distance, the light-emitting surface 21 of the third light-emitting element 20C can be located more on the front side or the back side than the light-emitting surface 21 of the first light-emitting element 20A is by the second distance, and a difference between the first distance and the second distance can be in a range from 0 μm to 10 μm.

When the plurality of light-emitting elements 20 include the two light-emitting elements 20 that emit lights having different emission peak wavelengths, the positions of the light-emitting surfaces 21 are relatively offset in accordance with the wavelengths of the lights emitted from the light-emitting elements 20 in some cases. For example, when the plurality of light-emitting elements 20 include the two or more light-emitting elements 20 that emit lights of colors different from each other and the lens member 80 includes the plurality of lens surfaces 81 having the same curvature, the positions of the light-emitting surfaces 21 may be relatively adjusted in consideration of an influence of a difference between the wavelengths on the optical action by the lens surfaces 81.

At this time, in the light-emitting device 1, the light-emitting surface 21 of the first light-emitting element 20A and the light-emitting surface 21 of the second light-emitting element 20B are offset in the front-rear direction, not only due to a difference in the height caused by the warp of the base 10 described above, but also according to a difference between the wavelength of the light emitted from the first light-emitting element 20A and the wavelength of the light emitted from the second light-emitting element 20B. Similarly, the light-emitting surface 21 of the first light-emitting element 20A and the light-emitting surface 21 of the third light-emitting element 20C are further offset in the front-rear direction according to a difference between the wavelength of the light emitted from the first light-emitting element 20A and the wavelength of the light emitted from the third light-emitting element 20C.

When such an adjustment is performed, there may be a difference between the offset of the second light-emitting element 20B with respect to the first light-emitting element 20A and the offset of the third light-emitting element 20C with respect to the first light-emitting element 20A due to the influence of the adjustment. In other words, in the light-emitting device 1, the second light-emitting element 20B and the third light-emitting element 20C may emit the lights of colors different from each other, and have the same distance from the first light-emitting element 20A or the center of the warp of the mounting surface 11D may be the same, and the first distance and the second distance may be different.

When the second light-emitting element 20B and the third light-emitting element 20C emit lights of colors different from each other, the difference between the first distance and the second distance can be in a range from 1 μm to 50 μm. In this case, a difference between the emission peak wavelength of the light emitted from the second light-emitting element 20B and the emission peak wavelength of the light emitted from the third light-emitting element 20C can be in a range from 40 nm to 220 nm.

When the plurality of light-emitting elements 20 include the two or more light-emitting elements 20 that emit lights of colors different from each other and the plurality of light-emitting elements 20 that emit lights of the same color, the plurality of light-emitting elements 20 are preferably arranged side by side such that no light-emitting elements 20 that emit lights of different colors are disposed between the plurality of light-emitting elements 20 that emit lights of the same color. This arrangement facilitates the connection of the wirings 60.

Therefore, in the light-emitting device 1, when the plurality of light-emitting elements 20 include the two or more light-emitting elements 20 that emit lights of colors different from each other, the second light-emitting element 20B and the third light-emitting element 20C may emit lights of colors different from each other. This arrangement facilitates the connection of the wirings 60.

When the plurality of light-emitting elements 20 are constituted by the plurality of light-emitting elements 20 that emit first light and one or more light-emitting elements 20 that emit second light different from the first light, and the number of the light-emitting elements 20 that emit the second light is equal to or less than the number of the light-emitting elements 20 that emit the first light, the light-emitting elements 20 that emit the first light are preferably disposed at positions closest to the center of the warp of the mounting surface 11D in the light-emitting device 1.

In the light-emitting device 1, the plurality of submounts 30 are disposed on the mounting surface 11D. The plurality of light-emitting elements 20 are disposed on the plurality of submounts 30. Via the submount 30, a height of a light-emitting point of the light emitted from the light-emitting element 20 can be adjusted. Each of the submounts 30 is bonded to a corresponding one of the light-emitting element 20 on one bonding surface and bonded to the mounting surface 11D on the other bonding surface. Each of the light-emitting elements 20 is disposed over the mounting surface 11D via a corresponding one of the submounts 30. The light-emitting elements 20 can be disposed on the mounting surface 11D without via the submounts 30.

The submounts 30 are provided on the light-emitting elements 20 in a one-to-one relationship. The light-emitting device 1 includes the submounts 30, the number of which is the same as the number of light-emitting elements 20. The plurality of light-emitting elements 20 can be disposed on one submount 30.

The plurality of submounts 30 include the submount 30 on which the first light-emitting element 20A is disposed, the submount 30 on which the second light-emitting element 20B is disposed, and the submount 30 on which the third light-emitting element 20C is disposed. Hereinafter, they are respectively referred to as the first submount 30, the second submount 30, and the third submount 30 for distinction.

In the top view, the light-emitting surface 21 of the light-emitting element 20 is located on or near the lateral surface on the front side of each of the submounts 30. Therefore, the position of each of the submounts 30 can also correspond to the position of a corresponding one of the light-emitting elements 20. When the light-emitting surface 21 of the second light-emitting element 20B and the light-emitting surface 21 of the third light-emitting element 20C are both located more on the front side than the light-emitting surface 21 of the first light-emitting element 20A is, the lateral surface on the front side of the second submount 30 and the lateral surface on the front side of the third submount 30 are both located more on the front side than the lateral surface on the front side of the first submount 30 is. When the light-emitting surface 21 of the second light-emitting element 20B and the light-emitting surface 21 of the third light-emitting element 20C are both located more on the back side than the light-emitting surface 21 of the first light-emitting element 20A is, the lateral surface on the front side of the second submount 30 and the lateral surface on the front side of the third submount 30 are both located more on the back side than the lateral surface on the front side of the first submount 30 is.

In the light-emitting device 1, one or the plurality of reflective members 40 are disposed on the mounting surface 11D. One or the plurality of reflective members 40 are disposed at positions spaced apart forward from the plurality of light-emitting elements 20. The lights emitted from the plurality of light-emitting elements 20 are reflected upward by one or the plurality of reflective members 40. Each light is reflected by one or the plurality of light reflective surfaces 41. One or the plurality of light reflective surfaces 41 are irradiated with a main portion of at least one of lights. The 90% or more of the main portion of the irradiated light is reflected by one or the plurality of light reflective surfaces 41. The light reflective surface 41 is inclined with respect to a traveling direction of light passing through the optical axis at an angle of 45 degrees.

The reflective members 40 can be provided in a one-to-one relationship with the light-emitting elements 20. In other words, the reflective members 40, the number of which is the same as that of the light-emitting elements 20, are arranged. All the reflective members 40 have the same size and shape. The light reflective surface of one reflective member 40 is irradiated with the main portion of the light from one light-emitting element 20. The light reflective surface of one reflective member 40 can be irradiated with the main portions of the lights from the plurality of light-emitting elements 20. The plurality of reflective members 40 are arranged side by side in the same direction as the direction in which the plurality of light-emitting elements 20 are arranged in the top view.

In the light-emitting device 1, one or the plurality of protective elements 50 are disposed on the submount 30. One or the plurality of protective elements 50 can be disposed on the wiring pattern 13. The protective element 50 can be provided in a one-to-one relationship with the light-emitting element 20.

In the light-emitting device 1, the plurality of wirings 60 are bonded to the wiring pattern 13, the light-emitting elements 20, or the submounts 30. The plurality of wirings 60 electrically connect the plurality of light-emitting elements 20 to the base 10. When the wiring pattern 13 is provided on the frame portion 12B containing a ceramic as the main material, it is possible to easily achieve conduction with the wiring pattern provided on the outer surfaces such as the upper surface and the lower surface, through the inside of the frame portion 12B.

In the top view, the plurality of wirings 60 include a first wiring 60A having one end of bonding portions at both ends bonded to the second light-emitting element 20B or the submount 30 on which the second light-emitting element 20B is disposed and the other end bonded to the submount 30 on which the light-emitting element 20 adjacent to the second light-emitting element 20B is disposed or that light-emitting element 20.

In the top view, the plurality of wirings 60 include a second wiring 60B having one end of bonding portions at both ends bonded to the submount 30 on which the light-emitting element 20 adjacent to the third light-emitting element 20C is disposed or the light-emitting element 20 and the other end bonded to the third light-emitting element 20C or the submount 30 on which the third light-emitting element 20C is disposed.

In the top view, a first imaginary straight line L1 connecting the bonding portions at both ends of the first wiring 60A and a second imaginary straight line L2 connecting the bonding portions at both ends of the second wiring 60B are not parallel to each other. In the top view, an angle D1 formed by the first imaginary straight line with respect to an imaginary straight line L3 parallel to the light-emitting surface 21 of the first light-emitting element 20A and an angle D2 formed by the second imaginary straight line with respect to the imaginary straight line L3 are different (see FIG. 5A).

In the light-emitting device 1, the lid member 70 is disposed on the upper surface of the base 10. The lid member 70 is located higher than the stepped portion 12C. As a result of the lid member 70 being bonded, a closed space surrounded by the base 10 and the lid member 70 is generated. This space is a space in which the light-emitting elements 20 are arranged.

By bonding the lid member 70 to the base 10 under a predetermined atmosphere, the hermetically sealed closed space is created. When semiconductor laser elements are employed as the light-emitting elements 20, quality deterioration thereof due to dust gathering can be suppressed by hermetically sealing the space in which the semiconductor laser elements are disposed. The lid member 70 has transmissivity with respect to the lights emitted from the light-emitting elements 20. 90% or more of the main portion of the light emitted from the light-emitting element 20 passes through the lid member 70 and exits to the outside.

The lens member 80 is disposed above the lid member 70. The lens member 80 is fixed to the base 10. The lens member 80 is bonded to the lid member 70. The lens member 80 is fixed to the base 10 with the lid member 70 interposed therebetween. A plurality of lights having exited from the lid member 70 are incident on the lower surface 83 of the lens member 80. The light incident on the lens member 80 exits from the lens surface 81.

The lens member 80 is disposed on an upper side of one or the plurality of the reflective members 40. The lens surface 81 of the lens member 80 is disposed directly above the light reflective surface 41 of the reflective member 40. Light emitted from light-emitting element 20 and reflected by the reflective member 40 is incident on the lens member 80.

In the top view, the lens member 80 is disposed such that one or the plurality of lens surfaces 81 respectively overlaps with the light-emitting elements 20. The main portions of the lights emitted from the light-emitting elements 20 respectively exit from the plurality of lens surfaces 81. One light-emitting element 20 corresponds to one lens surface 81, and the light from a corresponding one of the light-emitting elements 20 exits from a corresponding one of the lens surfaces 81.

The light having passed through the lens surface 81 and exited from the lens member 80 is collimated light. The light need not be the collimated light but can be condensed light or diffused light. Each of the lens surfaces 81 gives the same optical action to the light passing through the lens surface 81. In each of the lens surfaces, the light having passed through the lens surface 81 and exited from the lens member 80 can become collimated light.

The lens member 80 includes the plurality of lens portions 84 respectively corresponding to the plurality of light-emitting elements 20. In the plurality of lens portions 84 corresponding to the plurality of light-emitting elements 20, the lens surfaces 81 of all the lens portions 84 have the same curvature. In a case in which lights having the same emission peak wavelength are emitted from the plurality of light-emitting elements 20, the lens surfaces 81 of the lens portions 84 preferably have the same curvature.

The plurality of lens portions 84 include the first lens portion 84 through which light emitted from the first light-emitting element 20A passes, the second lens portion 84 through which light emitted from the second light-emitting element 20B passes, and the third lens portion 84 through which light emitted from the third light-emitting element 20C passes. The plurality of lens portions 84 further include the fourth lens portion 84 through which light emitted from the fourth light-emitting element 20D passes.

The warp caused on the mounting surface 11D affects the heights of the light-emitting elements 20 and the reflective members 40 disposed on/over the mounting surface 11D. The height at which the first light-emitting element 20A and the reflective member 40 corresponding to the first light-emitting element 20A are disposed are different from the height at which the second light-emitting element 20B and the reflective member 40 corresponding to the second light-emitting element 20B are disposed. Thus, the light emitted from the first light-emitting element 20A and the light emitted from the second light-emitting element 20B have different optical path lengths of the lights reaching the lower surface 83 of the lens member 80 or the lens surfaces 81 from the reflective members 40. FIG. 6A illustrates the difference in the optical path length in a case in which the warp of the mounting surface 11D has a shape such that the height at the position away from the center of the warp is lower than the height at the center of the warp. FIG. 6B illustrates the difference in the optical path length in a case in which the warp of the mounting surface 11D has a shape such that the height at the position away from the center of the warp is higher than the height at the center of the warp. In FIGS. 6A and 6B, the warp of the mounting surface 11D is exaggerated to facilitate understanding of the height differences. Therefore, by adjusting the positions of the light-emitting elements 20 as in the light-emitting device 1, the difference in the optical path length can be reduced, and the quality of the light emitted from the light-emitting device 1 can be improved. The same applies to the relationship between the first light-emitting element 20A and the third light-emitting element 20C.

It should be noted that the target, the optical path lengths from which are uniformed, can be the lid member 70, not the lens member 80. In a case in which the light-emitting device 1 emits lights emitted from the plurality of semiconductor laser elements at the same divergence angle, when the optical path lengths are uniform, the light having the same magnitude can be emitted. This can facilitate optical control and allow reduction in the size of a device for optical control. From this point of view as well, improvement in the quality of light can be achieved.

### Second Embodiment

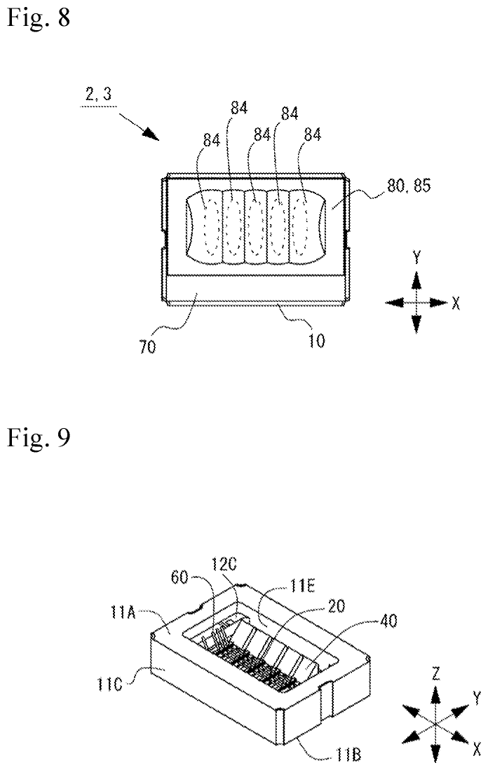

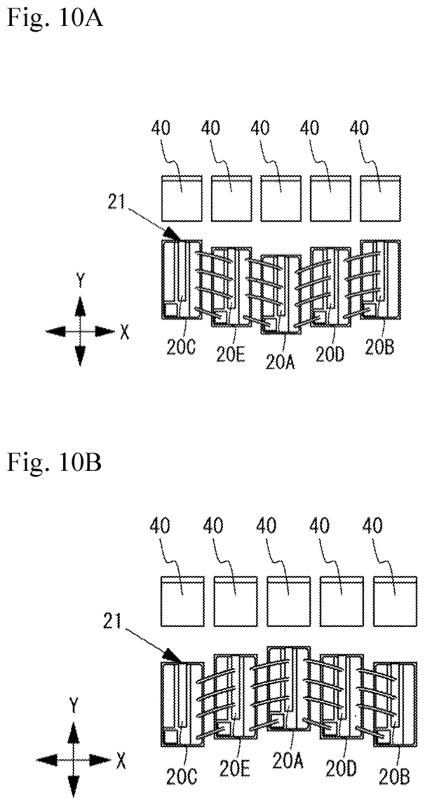

A light-emitting device 2 according to the second embodiment will now be described. FIG. 4 and FIGS. 7 to 10B are diagrams for describing an exemplary form of the light-emitting device 2. FIG. 4 is a cross-sectional view of the base 10. FIG. 7 is a perspective view of the light-emitting device 2. FIG. 8 is a top view of the light-emitting device 2. The elliptical dotted lines in FIG. 8 represent outer shapes of lights emitted from the light-emitting device 2. FIG. 9 is a perspective view for describing the components disposed inside the light-emitting device 2. FIGS. 10A and 10B are diagrams for describing a position of each of the light-emitting surfaces 21 of the plurality of light-emitting elements 20 disposed over the mounting surface 11D in the light-emitting device 2.

The light-emitting device 2 includes a plurality of components. The plurality of components include the base 10, the plurality of light-emitting elements 20, the plurality of submounts 30, one or the plurality of reflective members 40, one or the plurality of protective elements 50, the plurality of wirings 60, the lid member 70, and the lens member 80.

Among the descriptions related to the light-emitting device 1 and the components of the first embodiment described above, all contents except the contents that can be said to be inconsistent from the diagrams of FIGS. 7 to 10B according to the light-emitting device 2 apply to the description of the light-emitting device 2. All contents not inconsistent will not be described again in order to avoid duplication.

### Light-Emitting Device 2

In the light-emitting device 2, the plurality of light-emitting elements 20 further include one or more fifth light-emitting elements 20E disposed between the first light-emitting element 20A and the third light-emitting element 20C. One or more fourth light-emitting elements 20D and one or more fifth light-emitting elements 20E are disposed, on the mounting surface 11D, more away from the center of the warp than the first light-emitting element 20A.

It can be said that the third light-emitting element 20C is the light-emitting element 20 disposed at a position farthest from the first light-emitting element 20A in the second direction among the plurality of light-emitting elements 20 disposed over the mounting surface 11D at positions spaced apart from the first light-emitting element 20A in the second direction. In other words, no light-emitting element is disposed over the mounting surface 11D of the base 10 at a position farther away from or beyond the third light-emitting element 20C in the second direction.

In the light-emitting device 2, the second light-emitting element 20B is positioned more on the front side than the light-emitting surface 21 of the first light-emitting element 20A and the light-emitting surface 21 of the fourth light-emitting element 20D are, or is positioned more on the back side than the light-emitting surface 21 of the first light-emitting element 20A and the light-emitting surface 21 of the fourth light-emitting element 20D are. The third light-emitting element 20C is positioned more on the front side than the light-emitting surface 21 of the first light-emitting element 20A and the light-emitting surface 21 of the fifth light-emitting element 20E are, or is positioned more on the back side than the light-emitting surface 21 of the first light-emitting element 20A and the light-emitting surface 21 of the fifth light-emitting element 20E are.

In the light-emitting device 2, the one or more fourth light-emitting elements 20D include the fourth light-emitting element 20D whose light-emitting surface 21 is located more on the front side or the back side than the light-emitting surface 21 of the first light-emitting element 20A is. The one or more fifth light-emitting elements 20E include the fifth light-emitting element 20E whose light-emitting surface 21 is located more on the front side or the back side than the light-emitting surface 21 of the first light-emitting element 20A is.

In the light-emitting device 2, the plurality of light-emitting elements 20 include the fourth light-emitting element 20D and the fifth light-emitting element 20E each located more on the front side than the light-emitting surface 21 of the first light-emitting element 20A is, or the fourth light-emitting element 20D and the fifth light-emitting element 20E each located more on the back side than the light-emitting surface 21 of the first light-emitting element 20A is.

In the light-emitting device 2, the plurality of light-emitting elements 20 are separated at an equal interval in the lateral direction. Furthermore, the distance between in the front-rear direction the light-emitting surface 21 of the second light-emitting element 20B and the light-emitting surface 21 of the fourth light-emitting element 20D disposed adjacent to the second light-emitting element 20B is greater than the distance in the front-rear direction between the light-emitting surface 21 of the first light-emitting element 20A and the light-emitting surface 21 of the fourth light-emitting element 20D disposed adjacent to the first light-emitting element 20A. Furthermore, the distance in the front-rear direction between the light-emitting surface 21 of the third light-emitting element 20C and the light-emitting surface 21 of the fifth light-emitting element 20E disposed adjacent to the third light-emitting element 20C is greater than the distance in the front-rear direction between the light-emitting surface 21 of the first light-emitting element 20A and the light-emitting surface 21 of the fifth light-emitting element 20E disposed adjacent to the first light-emitting element 20A. When the warp of the mounting surface 11D is not proportional to the distance from the center of the warp and the amount of change in the warp is greater at the end of the mounting surface 11D, adjusting the positions of the plurality of light-emitting elements 20 in this manner can improve the quality of the light emitted from the light-emitting device.

In the light-emitting device 2, the fourth light-emitting element 20D disposed adjacent to the second light-emitting element 20B can be the fourth light-emitting element 20D disposed adjacent to the first light-emitting element 20A. The fifth light-emitting element 20E disposed adjacent to the third light-emitting element 20C can be the fifth light-emitting element 20E disposed adjacent to the first light-emitting element 20A.

### Third Embodiment

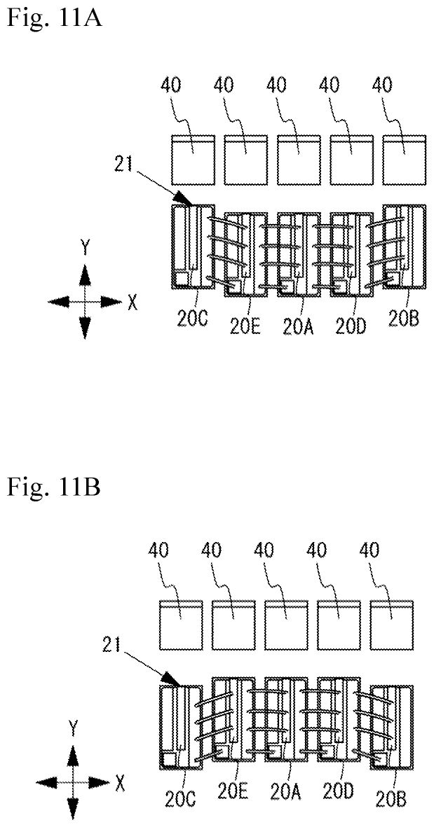

A light-emitting device 3 according to the third embodiment will be described. FIG. 4, FIGS. 7 to 9, and FIGS. 11A and 11B are drawings for describing an exemplary form of the light-emitting device 3. FIG. 4 is a cross-sectional view of the base 10. FIG. 7 is a perspective view of the light-emitting device 3. FIG. 8 is a top view of the light-emitting device 3. The elliptical dotted lines in FIG. 8 represent outer shapes of lights emitted from the light-emitting device 3. FIG. 9 is a perspective view for describing the components disposed inside the light-emitting device 3. FIGS. 11A and 11B are diagrams for describing a position of each of the light-emitting surfaces 21 of the plurality of light-emitting elements 20 disposed over the mounting surface 11D in the light-emitting device 3.

The light-emitting device 3 includes a plurality of components. The plurality of components include the base 10, the plurality of light-emitting elements 20, the plurality of submounts 30, one or the plurality of reflective members 40, one or the plurality of protective elements 50, the plurality of wirings 60, the lid member 70, and the lens member 80.

Among the descriptions related to the light-emitting device 1, the light-emitting device 2, and the components described above, all contents except the contents that can be said to be inconsistent from the diagrams of FIGS. 1 to 4 and FIGS. 10A and 10B according to the light-emitting device 3 apply to the description of the light-emitting device 3. All contents not inconsistent will not be described again in order to avoid duplication.

### Light-Emitting Device 3

In the light-emitting device 3, one or more fourth light-emitting elements 20D include the fourth light-emitting element 20D whose light-emitting surface 21 is not offset in the front-rear direction with respect to the light-emitting surface 21 of the first light-emitting element 20A. One or more fifth light-emitting elements 20E include the fifth light-emitting element 20E whose light-emitting surface 21 is not offset in the front-rear direction with respect to the light-emitting surface 21 of the first light-emitting element 20A.

Here, a distance from the light-emitting surface 21 of the fourth light-emitting element 20D to the light-emitting surface 21 of the second light-emitting element 20B in the front-rear direction is referred to as a third distance, and a distance from the light-emitting surface 21 of the fifth light-emitting element 20E to the light-emitting surface 21 of the third light-emitting element 20C in the front-rear direction is referred to as a fourth distance.

In the light-emitting device 3, one or more fourth light-emitting elements 20D include the fourth light-emitting element 20D having the third distance equal to the first distance. The one or more fourth light-emitting elements 20D do not include the fourth light-emitting element 20D having the third distance different from the first distance. Here, “equal” means that the difference between the first distance and the third distance is within ±5 μm, and “different” means that the difference between the first distance and the third distance is more than ±5 μm.

In the light-emitting device 3, one or more fifth light-emitting elements 20E include the fifth light-emitting element 20E having the fourth distance equal to the second distance. The one or more fifth light-emitting elements 20E do not include the fifth light-emitting element 20E having the fourth distance different from the second distance. Here, “equal” means that the difference between the second distance and the fourth distance is within ±5 μm, and “different” means that the difference between the second distance and the fourth distance is more than ±5 μm.

In the light-emitting device 3, among the plurality of light-emitting elements 20, only the second light-emitting element 20B and the third light-emitting element 20C are the light-emitting elements 20 located more on the front side or the back side than the light-emitting surface 21 of the first light-emitting element 20A is. When the warp of the mounting surface 11D is not proportional to the distance from the center of the warp and the amount of change in the warp is greater at the end of the mounting surface 11D, while the positions of the second light-emitting element 20B and the third light-emitting element 20C are adjusted in the front-rear direction, the light-emitting element 20 disposed between the first light-emitting element 20A and the second light-emitting element 20B and the light-emitting element 20 disposed between the first light-emitting element 20A and the third light-emitting element 20C are possibly not adjusted. In this case as well, the quality of the light emitted from the light-emitting device can be improved.

Although the light-emitting device 1 to the light-emitting device 3 have been described above, both the second light-emitting element 20B and the third light-emitting element 20C are not necessarily offset in the same direction with respect to the first light-emitting element 20A in these light-emitting devices depending on the magnitude relationship between the amount of offset according to the difference in the height caused by the warp of the mounting surface 11D and the amount of offset according to the difference in color or wavelength between the emitted lights.

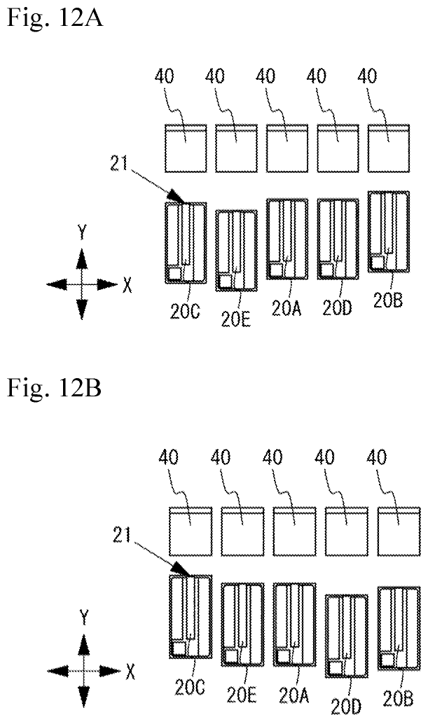

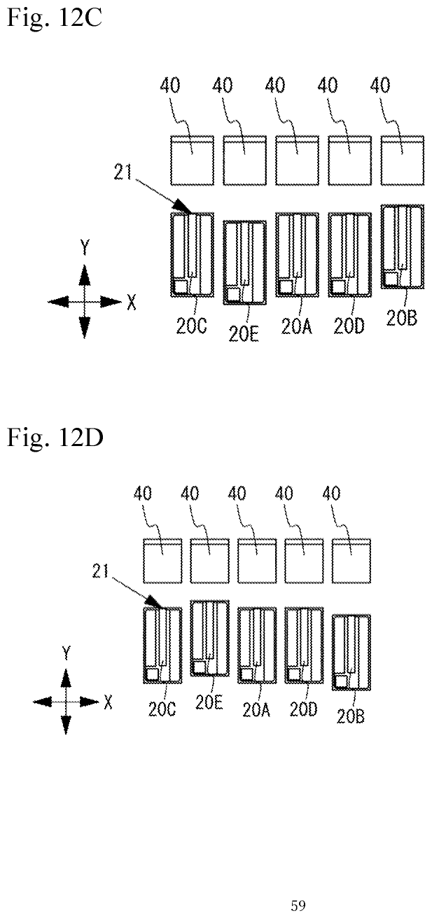

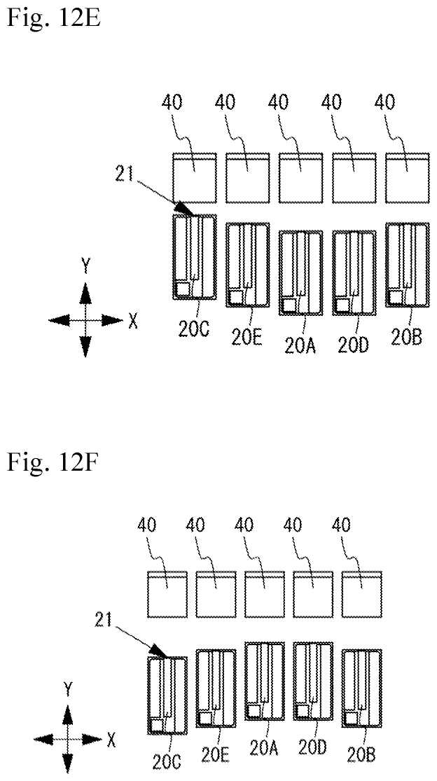

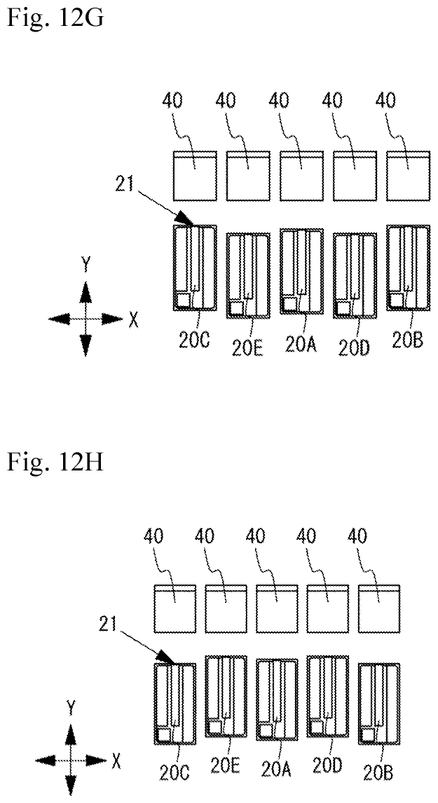

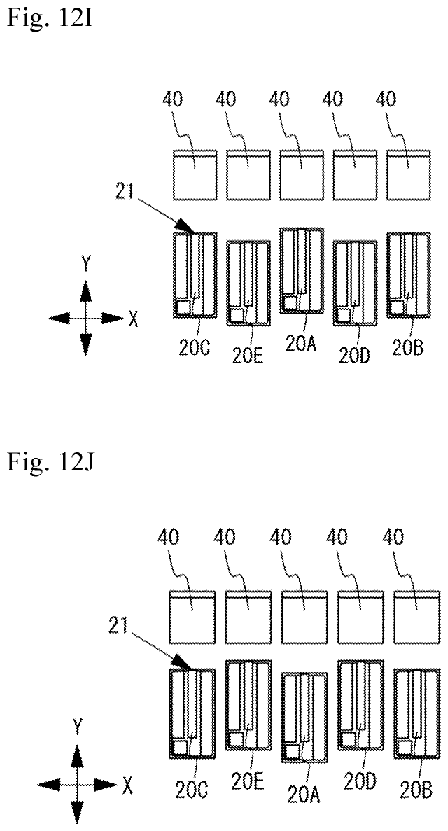

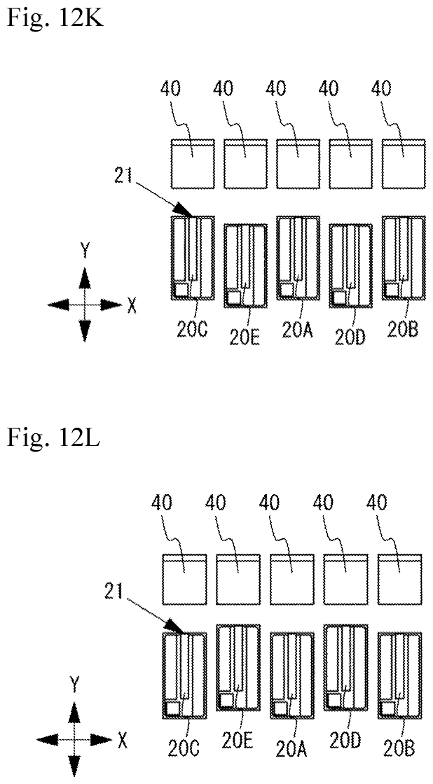

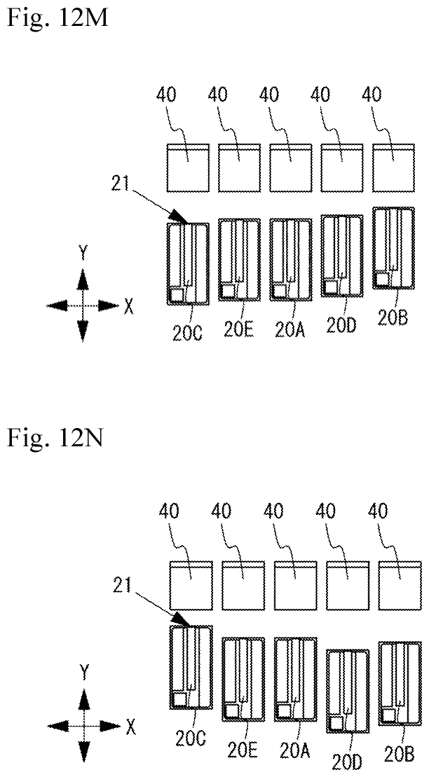

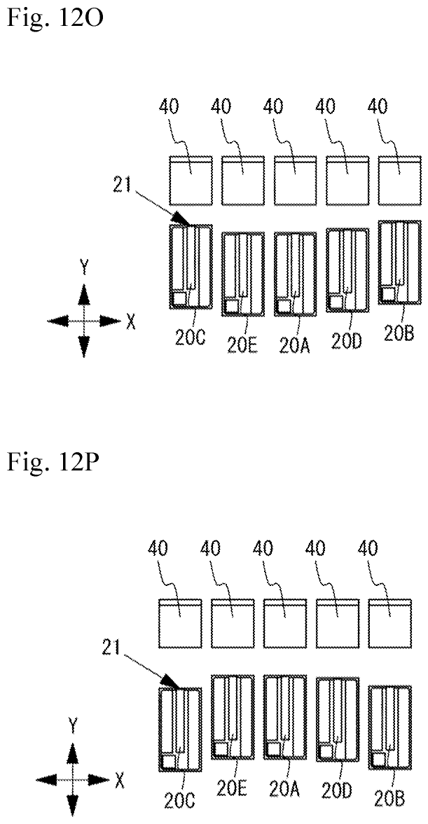

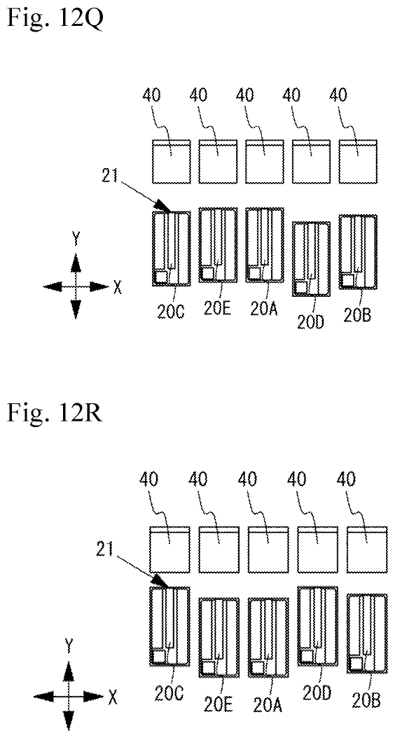

In the light-emitting device according to the embodiment, when the first light-emitting element 20A and the second light-emitting element 20B emit light of the same color and the third light-emitting element 20C emits light of a color different from that of the first light-emitting element 20A, the light-emitting surface 21 of the second light-emitting element 20B can be located more on the front side than the light-emitting surface 21 of the first light-emitting element 20A is, and the light-emitting surface 21 of the third light-emitting element 20C can be located more on the back side than the light-emitting surface 21 of the first light-emitting element 20A is, in some cases (see FIG. 12A).

In the light-emitting device according to the embodiment, when the first light-emitting element 20A and the second light-emitting element 20B emit light of the same color and the third light-emitting element 20C emits light of a color different from that of the first light-emitting element 20A, the light-emitting surface 21 of the second light-emitting element 20B can be located more on the back side than the light-emitting surface 21 of the first light-emitting element 20A is, and the light-emitting surface 21 of the third light-emitting element 20C can be located more on the front side than the light-emitting surface 21 of the first light-emitting element 20A is, in some cases (see FIG. 12B).

In the light-emitting device according to the embodiment, when the first light-emitting element 20A and the second light-emitting element 20B emit light of the same color and the third light-emitting element 20C emits light of a color different from that of the first light-emitting element 20A, the light-emitting surface 21 of the second light-emitting element 20B is located more on the front side than the light-emitting surface 21 of the first light-emitting element 20A is, and the light-emitting surface 21 of the third light-emitting element 20C is located at the same position in the front-rear direction as the light-emitting surface 21 of the first light-emitting element 20A, in some cases (see FIG. 12C).

In the light-emitting device according to the embodiment, when the first light-emitting element 20A and the second light-emitting element 20B emit light of the same color and the third light-emitting element 20C emits light of a color different from that of the first light-emitting element 20A, the light-emitting surface 21 of the second light-emitting element 20B can be located more on the back side than the light-emitting surface 21 of the first light-emitting element 20A is, and the light-emitting surface 21 of the third light-emitting element 20C can be located at the same position in the front-rear direction as the light-emitting surface 21 of the first light-emitting element 20A, in some cases (see FIG. 12D).

In the light-emitting device according to the embodiment, when the first light-emitting element 20A and the second light-emitting element 20B emit light of the same color and the third light-emitting element 20C emits light of a color different from that of the first light-emitting element 20A, both the light-emitting surface 21 of the second light-emitting element 20B and the light-emitting surface 21 of the third light-emitting element 20C can be located more on the front side or the back side than the light-emitting surface 21 of the first light-emitting element 20A is, and the first distance can be different from the second distance, in some cases (see FIGS. 12E and 12F).

In the light-emitting device according to the embodiment, when the second light-emitting element 20B and the third light-emitting element 20C emit light of the same color and the first light-emitting element 20A emits light of a color different from that of the second light-emitting element 20B, both the light-emitting surface 21 of the second light-emitting element 20B and the light-emitting surface 21 of the third light-emitting element 20C can be located more on the front side or the back side than the light-emitting surface 21 of the first light-emitting element 20A is in some cases. However, the first distance does not match the amount of offset according to the difference between the wavelength of the light emitted from the first light-emitting element 20A and the wavelength of the light emitted from the second light-emitting element 20B, and the second distance does not match the amount of offset according to the difference between the wavelength of the light emitted from the first light-emitting element 20A and the wavelength of the light emitted from the third light-emitting element 20C (see FIGS. 12G and 12H).

In the light-emitting device according to the embodiment, in a case in which the second light-emitting element 20B and the third light-emitting element 20C emit light of the same color and the first light-emitting element 20A emits light of a color different from that of the second light-emitting element 20B, both the light-emitting surface 21 of the second light-emitting element 20B and the light-emitting surface 21 of the third light-emitting element 20C can be located more on the back side than the light-emitting surface 21 of the first light-emitting element 20A is in some cases even when the warp of the mounting surface 11D has a shape such that the height at the position away from the center of the warp is lower than the height at the center of the warp (see FIG. 12I).

In the light-emitting device according to the embodiment, in a case in which the second light-emitting element 20B and the third light-emitting element 20C emit light of the same color and the first light-emitting element 20A emits light of a color different from that of the second light-emitting element 20B, both the light-emitting surface 21 of the second light-emitting element 20B and the light-emitting surface 21 of the third light-emitting element 20C can be located more on the front side than the light-emitting surface 21 of the first light-emitting element 20A is in some cases even when the warp of the mounting surface 11D has a shape such that the height at the position away from the center of the warp is higher than the height at the center of the warp (see FIG. 12J).

In the light-emitting device according to the embodiment, when the second light-emitting element 20B and the third light-emitting element 20C emit light of the same color and the first light-emitting element 20A emits light of a color different from that of the second light-emitting element 20B, both the light-emitting surface 21 of the second light-emitting element 20B and the light-emitting surface 21 of the third light-emitting element 20C can be located at the same position in the front-rear direction as the light-emitting surface 21 of the first light-emitting element 20A in some cases. However, the amount of offset according to the difference in wavelength is the same as the amount of offset according to the difference in the height of the mounting surface 11D, and the directions of offset are opposite to each other (see FIGS. 12K and 12L).

In the light-emitting device according to the embodiment, when the first light-emitting element 20A, the second light-emitting element 20B, and the third light-emitting element 20C emit lights of colors different from one another, the light-emitting surface 21 of the second light-emitting element 20B can be located more on the front side than the light-emitting surface 21 of the first light-emitting element 20A is, and the light-emitting surface 21 of the third light-emitting element 20C can be located more on the back side than the light-emitting surface 21 of the first light-emitting element 20A is, in some cases. However, the first distance does not match the amount of offset according to the difference between the wavelength of the light emitted from the first light-emitting element 20A and the wavelength of the light emitted from the second light-emitting element 20B, and the second distance does not match the amount of offset according to the difference between the wavelength of the light emitted from the first light-emitting element 20A and the wavelength of the light emitted from the third light-emitting element 20C (see FIG. 12M).

In the light-emitting device according to the embodiment, when the first light-emitting element 20A, the second light-emitting element 20B, and the third light-emitting element 20C emit lights of colors different from one another, the light-emitting surface 21 of the second light-emitting element 20B can be located more on the back side than the light-emitting surface 21 of the first light-emitting element 20A is, and the light-emitting surface 21 of the third light-emitting element 20C can be located more on the front side than the light-emitting surface 21 of the first light-emitting element 20A is, in some cases. However, the first distance does not match the amount of offset according to the difference between the wavelength of the light emitted from the first light-emitting element 20A and the wavelength of the light emitted from the second light-emitting element 20B, and the second distance does not match the amount of offset according to the difference between the wavelength of the light emitted from the first light-emitting element 20A and the wavelength of the light emitted from the third light-emitting element 20C (see FIG. 12N).

In the light-emitting device according to the embodiment, when the first light-emitting element 20A, the second light-emitting element 20B, and the third light-emitting element 20C emit lights of colors different from one another, both the light-emitting surface 21 of the second light-emitting element 20B and the light-emitting surface 21 of the third light-emitting element 20C can be located more on the front side or the back side than the light-emitting surface 21 of the first light-emitting element 20A is in some cases. However, the first distance does not match the amount of offset according to the difference between the wavelength of the light emitted from the first light-emitting element 20A and the wavelength of the light emitted from the second light-emitting element 20B, and the second distance does not match the amount of offset according to the difference between the wavelength of the light emitted from the first light-emitting element 20A and the wavelength of the light emitted from the third light-emitting element 20C. Further, the first distance and the second distance are different from each other (see FIGS. 12O and 12P).

In the light-emitting device according to the embodiment, in a case in which the first light-emitting element 20A, the second light-emitting element 20B, and the third light-emitting element 20C emit lights of colors different from one another, both the light-emitting surface 21 of the second light-emitting element 20B and the light-emitting surface 21 of the third light-emitting element 20C can be located more on the back side than the light-emitting surface 21 of the first light-emitting element 20A is in some cases even when the warp of the mounting surface 11D has a shape such that the height at the position away from the center of the warp is lower than the height at the center of the warp (see FIG. 12Q).

In the light-emitting device according to the embodiment, in a case in which the first light-emitting element 20A, the second light-emitting element 20B, and the third light-emitting element 20C emit lights of colors different from one another, both the light-emitting surface 21 of the second light-emitting element 20B and the light-emitting surface 21 of the third light-emitting element 20C can be located more on the front side than the light-emitting surface 21 of the first light-emitting element 20A is in some cases even when the warp of the mounting surface 11D has a shape such that the height at the position away from the center of the warp is higher than the height at the center of the warp (see FIG. 12R).

When the plurality of light-emitting elements 20 include the two or more light-emitting elements 20 that emit lights of colors different from each other, while the positions of the respective light-emitting surfaces 21 of the light-emitting elements 20 that emit light of the same color are adjusted according to a difference in the height of the mounting surface 11D, the positions of the respective light-emitting surfaces 21 of the light-emitting elements 20 that emit lights of colors different from each other need not be adjusted according to a difference in the height of the mounting surface 11D in some cases.

When the plurality of light-emitting elements 20 include the light-emitting element 20 that emits first light, the light-emitting element 20 that emits second light different from the first light, and the light-emitting element 20 that emits third light different from the first light and the second light, the positions of the light-emitting surfaces 21 of these three light-emitting elements 20 can be adjusted according to a difference in the wavelength.

In the light-emitting device 1, when the warp of the mounting surface 11D of the base 10 has a shape such that the height of the mounting surface 11D is lower at a position farther from the center of the warp, it may be preferable that the light-emitting element 20 that emits light having the shortest emission peak wavelength among the three light-emitting elements 20 is set as the first light-emitting element 20A, and the remaining two light-emitting elements 20 are set as the second light-emitting element 20B and the third light-emitting element 20C in some cases. In the case of the warp having such a shape, considering only the warp of the base 10, the light-emitting surface 21 of the second light-emitting element 20B and the light-emitting surface 21 of the third light-emitting element 20C are located more on the front side than the light-emitting surface 21 of the first light-emitting element 20A is. Therefore, a part or all of the offset according to a difference in wavelength and the offset according to the warp are offset, and the amount of offset between the first light-emitting element 20A, the second light-emitting element 20B, and the third light-emitting element 20C is reduced as a whole. Therefore, the mounting surface 11D can be kept small, which contributes to downsizing of the light-emitting device 1.

For example, in the light-emitting device 1, it may be preferable that the first light-emitting element 20A is the light-emitting element 20 that emits blue light when the warp of the mounting surface 11D of the base 10 has a shape such that the height of the mounting surface 11D is lower at a position more away from the center of the warp, the plurality of light-emitting elements 20 include the light-emitting element 20 that emits red light, the light-emitting element 20 that emits green light, and the light-emitting element 20 that emits blue light, and the curvatures of the three lens surfaces 81 through which the respective lights emitted from the three light-emitting elements 20 pass are the same.

In a similar way of thinking, in the light-emitting device 1, when the warp of the mounting surface 11D of the base 10 has a shape such that the height of the mounting surface 11D is higher at a position more away from the center of the warp, when adjustment is performed considering only a difference in wavelength, it is preferable that the light-emitting element 20 whose light-emitting surface 21 is located at the rearmost position among the three light-emitting elements 20 is set as the first light-emitting element 20A, and the remaining two light-emitting elements 20 are set as the second light-emitting element 20B and the third light-emitting element 20C.

For example, in the light-emitting device 1, it is preferable that the first light-emitting element 20A is the light-emitting element 20 that emits red light when the warp of the mounting surface 11D of the base 10 has a shape such that the height of the mounting surface 11D is higher at a position more away from the center of the warp, the plurality of light-emitting elements 20 include the light-emitting element 20 that emits red light, the light-emitting element 20 that emits green light, and the light-emitting element 20 that emits blue light, and the curvatures of the three lens surfaces 81 through which the respective lights emitted from the three light-emitting elements 20 pass are the same.

In a case in which the plurality of light-emitting elements 20 include the two light-emitting elements 20 having lengths different from each other in the front-rear direction, when the warp of the mounting surface 11D of the base 10 has a shape such that the height of the mounting surface 11D is lower at a position more away from the center of the warp, it is preferable that the shorter light-emitting element 20 in length in the front-rear direction of the two light-emitting elements 20 is set as the first light-emitting element 20A and the longer light-emitting element 20 in length is set as at least one of the second light-emitting element 20B and the third light-emitting element 20C. Therefore, the mounting surface 11D can be kept small, which contributes to downsizing of the light-emitting device 1.

Although the embodiments according to the present invention have been described above, the light-emitting device according to the present invention is not strictly limited to the light-emitting devices of the embodiments. In other words, the present invention may be achieved without being limited to the external shape or structure of the light-emitting device disclosed by each of the embodiments. The present invention can be applied without requiring all the components being sufficiently provided. For example, in a case in which some of the components of the light-emitting device disclosed by the embodiments are not stated in the claims, the degree of freedom in design by those skilled in the art such as substitutions, omissions, shape deformations, and material changes for those components is allowed, and then the invention stated in the claims being applied to those components is specified.

The light-emitting devices according to the embodiments can be used for projectors, vehicle headlights, head-mounted displays, lighting, displays, and the like.

What is claimed is:

1. A light-emitting device comprising:
a base having a mounting surface;
a first light-emitting element disposed over the mounting surface and configured to emit light forward from a light-emitting surface;
a second light-emitting element disposed over the mounting surface at a position on a first lateral side of the first light-emitting element and spaced apart from the first light-emitting element in a first direction, the second light-emitting element being configured to emit light forward from a light-emitting surface;
a third light-emitting element disposed over the mounting surface at a position on a second lateral side of the first light-emitting element and spaced apart from the first light-emitting element in a second direction opposite to the first direction, the third light-emitting element being configured to emit light forward from a light-emitting surface;
one or more reflective members disposed at a position spaced apart from the first light-emitting element, the second light-emitting element, and the third light-emitting element in a forward direction, the one or more reflective members being configured to reflect the light emitted from a corresponding one of the first light-emitting element, the second light-emitting element, and the third light-emitting element upward; and
a lens member disposed above the one or more reflective members and including a first lens portion through which the light emitted from the first light-emitting element passes, a second lens portion through which the light emitted from the second light-emitting element passes, and a third lens portion through which the light emitted from the third light-emitting element passes, wherein
the mounting surface of the base is warped such that a position on the mounting surface where the second light-emitting element is disposed and a position on the mounting surface where the third light-emitting element is disposed are lower than a position on the mounting surface where the first light-emitting element is disposed, and the light-emitting surface of the second light-emitting element and the light-emitting surface of the third light-emitting element are both located more on a front side than the light-emitting surface of the first light-emitting element, or
the mounting surface of the base is warped such that the position where the second light-emitting element is disposed and the position where the third light-emitting element is disposed are higher than the position where the first light-emitting element is disposed, and the light-emitting surface of the second light-emitting element and the light-emitting surface of the third light-emitting element are both located more on a back side than the light-emitting surface of the first light-emitting element.

2. The light-emitting device according to claim 1, wherein
the light-emitting surface of the second light-emitting element is located more on the front side or the back side than the light-emitting surface of the first light-emitting element by a range from 1 μm to 50 μm.

3. The light-emitting device according to claim 1, wherein
the light-emitting surface of the second light-emitting element is located more on the front side or the back side than the light-emitting surface of the first light-emitting element by a first distance,
the light-emitting surface of the third light-emitting element is located more on the front side or the back side than the light-emitting surface of the first light-emitting element by a second distance, and
a difference between the first distance and the second distance is in a range from 0 μm to 10 μm.

4. The light-emitting device according to claim 1, further comprising one or more fourth light-emitting elements disposed over the mounting surface between the first light-emitting element and the second light-emitting element.

5. The light-emitting device according to claim 4, further comprising one or more fifth light-emitting elements disposed over the mounting surface between the first light-emitting element and the third light-emitting element.

6. The light-emitting device according to claim 1, wherein
no light-emitting element is disposed over the mounting surface of the base at a position beyond the second light-emitting element in the first direction.

7. The light-emitting device according to claim 6, wherein
no light-emitting element is disposed over the mounting surface of the base at a position beyond the third light-emitting element in the second direction.

8. The light-emitting device according to claim 1, wherein
all of the first light-emitting element, the second light-emitting element, and the third light-emitting element are configured to emit lights of a same color.

9. The light-emitting device according to claim 1, wherein
a difference between an emission peak wavelength of the light emitted from the first light-emitting element and an emission peak wavelength of the light emitted from the second light-emitting element is in a range from 0 nm to 25 nm,
a difference between the emission peak wavelength of the light emitted from the first light-emitting element and an emission peak wavelength of the light emitted from the third light-emitting element is in a range from 0 nm to 25 nm, and
a difference between the emission peak wavelength of the light emitted from the second light-emitting element and the emission peak wavelength of the light emitted from the third light-emitting element is in a range from 0 nm to 25 nm.

10. The light-emitting device according to claim 1, wherein
the lens member is fixed to the base, and
in the lens member, a plurality of lens portions including the first lens portion, the second lens portion, and the third lens portion are linked to one another.

11. The light-emitting device according to claim 1, wherein
the first lens portion, the second lens portion, and the third lens portion have lens surfaces having a same curvature.

12. The light-emitting device according to claim 1, wherein
the mounting surface of the base is warped such that the position where the second light-emitting element is disposed and the position where the third light-emitting element is disposed are lower than a position where the first light-emitting element is disposed, and
the light-emitting surface of the second light-emitting element and the light-emitting surface of the third light-emitting element are both located more on the front side than the light-emitting surface of the first light-emitting element.

13. The light-emitting device according to claim 1, wherein
the base includes a base portion having the mounting surface and a frame portion surrounding the first light-emitting element, the second light-emitting element, and the third light-emitting element in a top view, and
the frame portion has a frame shape in which a width in a direction parallel to a lateral side of the frame shape is greater than a width in a direction parallel to a front side of the frame shape in the top view.

14. The light-emitting device according to claim 13, wherein
the base portion and the frame portion are formed of members containing respectively different materials as main materials.

15. The light-emitting device according to claim 13, wherein
the base portion is formed of a plate-shaped metal member containing a metal as a main material, and
the frame portion is formed of a frame-shaped ceramic member containing a ceramic as a main material.

16. The light-emitting device according to claim 1, further comprising:
a first submount on which the first light-emitting element is disposed and which is disposed on the mounting surface;
a second submount on which the second light-emitting element is disposed and which is disposed on the mounting surface; and
a third submount on which the third light-emitting element is disposed and which is disposed on the mounting surface, wherein
when the light-emitting surface of the second light-emitting element and the light-emitting surface of the third light-emitting element are both located more on the front side than the light-emitting surface of the first light-emitting element, a lateral surface on the front side of the second submount and a lateral surface on the front side of the third submount are both located more on the front side than a lateral surface on the front side of the first submount, and
when the light-emitting surface of the second light-emitting element and the light-emitting surface of the third light-emitting element are both located more on the back side than the light-emitting surface of the first light-emitting element, the lateral surface on the front side of the second submount and the lateral surface on the front side of the third submount are both located more on the back side than the lateral surface on the front side of the first submount.

17. The light-emitting device according to claim 1, wherein
the first light-emitting element, the second light-emitting element, and
the third light-emitting element are semiconductor laser elements.

18. A light-emitting device comprising:
a base having a mounting surface;
a first light-emitting element disposed over the mounting surface and configured to emit light forward from a light-emitting surface;
a second light-emitting element disposed over the mounting surface at a position on a first lateral side of the first light-emitting element and spaced apart from the first light-emitting element in a first direction, the second light-emitting element being configured to emit light forward from a light-emitting surface;
a third light-emitting element disposed over the mounting surface at a position on a second lateral side of the first light-emitting element and spaced apart from the first light-emitting element in a second direction opposite to the first direction, the third light-emitting element configured to emit light forward from a light-emitting surface;
one or more reflective members disposed at a position spaced apart from the first light-emitting element, the second light-emitting element, and the third light-emitting element in a forward direction, the one or more reflective members being configured to reflect the light emitted from a corresponding one of the first light-emitting element, the second light-emitting element, and the third light-emitting element upward; and
a lens member disposed above the one or more reflective members and including a first lens portion through which the light emitted from the first light-emitting element passes, a second lens portion through which the light emitted from the second light-emitting element passes, and a third lens portion through which the light emitted from the third light-emitting element passes, wherein
the light-emitting surface of the first light-emitting element and the light-emitting surface of the second light-emitting element are offset in a front-rear direction according to a difference between a height of the mounting surface at a position where the first light-emitting element is disposed and a height of the mounting surface at a position where the second light-emitting element is disposed, and
the light-emitting surface of the first light-emitting element and the light-emitting surface of the third light-emitting element are offset in the front-rear direction according to a difference between the height of the mounting surface at the position where the first light-emitting element is disposed and a height of the mounting surface at a position where the third light-emitting element is disposed.

19. The light-emitting device according to claim 18, wherein
the first light-emitting element, the second light-emitting element, and the third light-emitting element are disposed such that a respective one of the light-emitting surfaces is located according to a distance from a center of a warp of the mounting surface.

20. The light-emitting device according to claim 18, wherein
the light-emitting surface of the first light-emitting element and the light-emitting surface of the second light-emitting element are further offset in the front-rear direction according to a difference between a wavelength of the light emitted from the first light-emitting element and a wavelength of the light emitted from the second light-emitting element, and
the light-emitting surface of the first light-emitting element and the light-emitting surface of the third light-emitting element are further offset in the front-rear direction according to a difference between the wavelength of the light emitted from the first light-emitting element and a wavelength of the light emitted from the third light-emitting element.
